(19) United States
(12) Patent Application Publication
(10) Pub. No.: US 2025/0267961 A1
(43) Pub. Date: Aug. 21, 2025

(54) PIXEL SENSOR ARRAYS AND METHODS OF FORMATION

(71) Applicant: Taiwan Semiconductor Manufacturing Company, Ltd., Hsinchu (TW)

(72) Inventors: Chun-Liang LU, Tainan City (TW); Chun-Hao LIN, Tainan City (TW); Chun-Hao CHOU, Tainan City (TW); Kuo-Cheng LEE, Tainan City (TW)

(21) Appl. No.: 18/582,200

(22) Filed: Feb. 20, 2024

(51) Int. Cl. H01L 27/146

(52) U.S. Cl. CPC H10F 39/8027; H10F 39/024; H10F 39/026; H10F 39/8053

(57) ABSTRACT

Autofocus functionality is integrated into a pixel sensor array of an image sensor device described herein by including autofocus pixel sensors with imaging pixel sensors in the pixel sensor array. A metal grid structure may be included around the autofocus pixel sensors and the imaging pixel sensors in the pixel sensor array. Grid extensions of the metal grid structure extend laterally outward over at least a portion of photodiodes of the autofocus pixel sensors, thereby shielding the portions of the photodiodes from incident light. The autofocus pixel sensors may be arranged in pairs in the pixel sensor array such that opposing sides of the photodiodes of the autofocus pixel sensors in a pair are shielded by grid extensions. This results in a phase difference between the incident light sensed by the autofocus pixel sensors in the pair, which may be used for determining the focus of the pixel sensor array.

### BACKGROUND

A complementary metal oxide semiconductor (CMOS) image sensor may include a plurality of pixel sensors. A pixel sensor of the CMOS image sensor may include a transfer gate transistor, which may include a photodiode configured to convert photons of incident light into a photocurrent of electrons and a transfer gate configured to control the flow of the photocurrent between the photodiode and a drain region. The drain region may be configured to receive the photocurrent such that the photocurrent can be measured and/or transferred to other areas of the CMOS image sensor.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example of a pixel sensor described herein.

FIGS. 2A-2C are diagrams of examples of an image sensor device described herein.

FIGS. 3A and 3B are diagram of examples of pixel sensor arrays of a sensor die described herein.

FIGS. 4A-4D are diagrams of examples of pixel sensor arrays of a sensor die described herein.

FIG. 5 is a diagram of examples of pixel sensor arrays of a sensor die described herein.

FIG. 6 is a diagram of examples of pixel sensor arrays of a sensor die described herein.

FIG. 7 is a diagram of an example of a pixel sensor array of a sensor die described herein.

FIG. 8 is a diagram of an example of a pixel sensor array of a sensor die described herein.

FIG. 9 is a diagram of an example of a pixel sensor array of a sensor die described herein.

FIGS. 10A-10E are diagrams of an example implementation of forming a circuitry die (or a portion thereof) described herein.

FIGS. 11A-11F are diagrams of an example implementation of forming a sensor die (or a portion thereof) described herein.

FIGS. 12A-12F are diagrams of an example implementation of forming an image sensor device (or a portion thereof) described herein.

FIG. 13 is a flowchart of an example process associated with forming a pixel sensor array described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An image sensor device (e.g., a complementary metal oxide semiconductor (CMOS) image sensor device or another type of image sensor device) is a type of electronic semiconductor device that uses pixel sensors to generate a photocurrent based on light received at the pixel sensors. The magnitude of the photocurrent may be based on the intensity of the light, based on the wavelength of the light, and/or based on another attribute of the light. The photocurrent is then processed to generate an electronic image, an electronic video, and/or another type of electronic signal.

Typically, an electronic device (e.g., a camera device) that includes the image sensor device may also include a separate autofocus device. A portion of incident light that is received through a lens of the camera device is directed to the autofocus device for the purpose of performing autofocus functions of the camera device to focus a field of view onto the image sensor device. Having a separate image sensor device and a separate autofocus device in a camera device increases complexity and cost of the camera device in that additional circuitry is needed to interconnect the separate image sensor device and the separate autofocus device in the camera device. Moreover, having a separate image sensor device and a separate autofocus device in a camera device may prohibit reducing the size or form factor of the camera device in that the separate image sensor device and the separate autofocus device may occupy a relatively large area in the camera device. In addition, having a separate image sensor device and a separate autofocus device in a camera device may increase the manufacturing complexity of the camera device in that separate semiconductor manufacturing processes are used to manufacture the separate image sensor device and the separate autofocus device.

Some implementations described herein provide image sensor devices, and associated methods of formation, in which autofocus functionality is integrated into a pixel sensor array of the image sensor devices. This enables an image sensor device described herein to perform autofocus and image capture in the same pixel sensor array. In this way, integrating autofocus and image capture functionality into a single image sensor device may reduce complexity and cost of a camera device in which the image sensor device is included, in that the complexity of circuitry in the camera device may be reduced. Moreover, integrating autofocus and image capture functionality into a single image sensor device may reduce the size or formfactor of a camera device, in which the image sensor device is included, in that the image sensor device may occupy a lesser amount of area in the camera device relative to a separate image sensor device and a separate autofocus device. In addition, integrating autofocus and image capture functionality into a single image sensor device may reduce the manufacturing complexity of a camera device, in which the image sensor device is included, in that image sensor device can be manufactured with a single set of semiconductor manufacturing processes.

As described herein, autofocus functionality may be integrated into a pixel sensor array of an image sensor device described herein by including autofocus pixel sensors with imaging pixel sensors in the pixel sensor array. A metal grid structure is included around the autofocus pixel sensors and the imaging pixel sensors in the pixel sensor array. Moreover, the metal grid structure includes grid extensions, which are portions of the metal grid structure that extend laterally outward over at least a portion of photodiodes of the autofocus pixel sensors, thereby shielding the portions of the photodiodes from incident light. The autofocus pixel sensors may be arranged in pairs in the pixel sensor array such that opposing sides of the photodiodes of the autofocus pixel sensors in a pair are shielded by grid extensions. This results in a phase difference between the incident light sensed by the autofocus pixel sensors in the pair. The phase difference is used for determining the focus of the pixel sensor array. Thus, the grid extensions of the metal grid structure and the autofocus pixel sensors enable phase detection autofocus (PDAF) to be implemented “in-line” (e.g., integrated into) the pixel sensor array for high-speed autofocus performance. Moreover, grid extensions may cover different percentages of the area of the photodiodes of different autofocus pixel sensors, which enables high-speed autofocus performance in both high and low illumination scenarios.

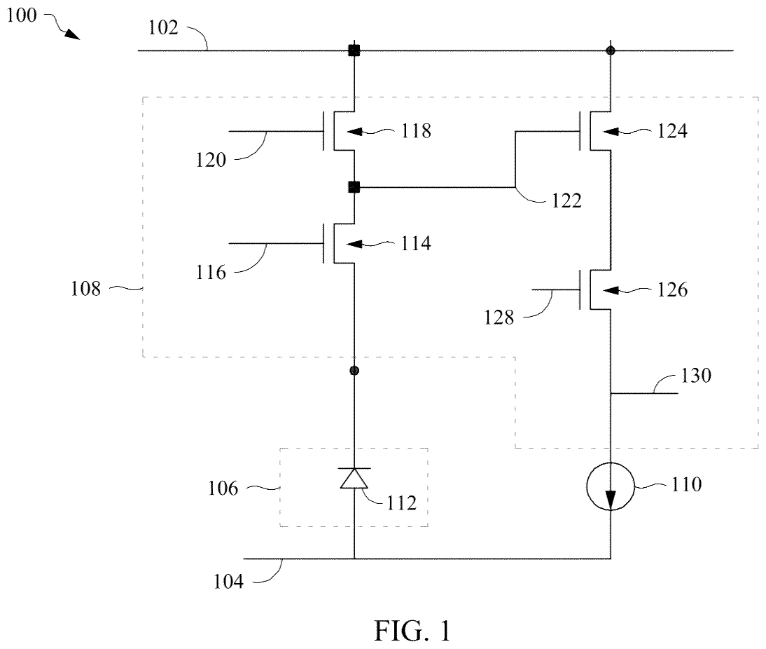

FIG. 1 is a diagram of an example of a pixel sensor 100 described herein. The pixel sensor 100 may include a front side pixel sensor (e.g., a pixel sensor that is configured to receive photons of light from a front side of a sensor die), a back side pixel sensor (e.g., a pixel sensor that is configured to receive photons of light from a back side of a sensor die), and/or another type of pixel sensor. The pixel sensor 100 may be electrically connected to a supply voltage (V_{dd}) 102 and an electrical ground 104.

The pixel sensor 100 includes a sensing region 106 that may be configured to sense and/or accumulate incident light (e.g., light directed toward the pixel sensor 100). The pixel sensor 100 also includes a control circuitry region 108. The control circuitry region 108 is electrically connected with the sensing region 106 and is configured to receive a photocurrent 110 that is generated by the sensing region 106. Moreover, the control circuitry region 108 is configured to transfer the photocurrent 110 from the sensing region 106 to downstream circuits such as amplifiers or analog-to-digital (AD) converters, among other examples.

The sensing region 106 includes a photodiode 112. The photodiode 112 may absorb and accumulate photons of the incident light, and may generate the photocurrent 110 based on absorbed photons. The magnitude of the photocurrent 110 is based on the amount of light collected in the photodiode 112. Thus, the accumulation of photons in the photodiode 112 generates a build-up of electrical charge that represents the intensity or brightness of the incident light (e.g., a greater amount of charge may correspond to a greater intensity or brightness, and a lower amount of charge may correspond to a lower intensity or brightness).

The photodiode 112 is electrically connected with a source of a transfer gate 114 in the control circuitry region 108. The transfer gate 114 is configured to control the transfer of the photocurrent 110 from the photodiode 112. The photocurrent 110 is provided from the source of the transfer gate 114 to a drain of the transfer gate 114 based on selectively switching a gate of the transfer gate 114. The gate of the transfer gate 114 may be selectively switched by applying a transfer voltage (Vₜₓ) 116 to the transfer gate 114. In some implementations, the transfer voltage 116 being applied to the transfer gate 114 causes a conductive channel to form between the source and the drain of the transfer gate 114, which enables the photocurrent 110 to traverse along the conductive channel from the source to the drain. In some implementations, the transfer voltage 116 being removed from the transfer gate 114 (or the absence of the transfer voltage 116) causes the conductive channel to be removed such that the photocurrent 110 cannot pass from the source to the drain.

The control circuitry region 108 further includes a reset gate 118. The reset gate 118 is electrically connected to the supply voltage 102. The reset gate 118 may be controlled by a reset voltage (Vᵣₛₜ) 120. The transfer gate 114 and the reset gate 118 may be electrically coupled with a floating diffusion node 122. The reset voltage 120 may be applied to the reset gate 118 to pull the drain of the transfer gate 114 to a high voltage (e.g., to the supply voltage 102) to “reset” the floating diffusion node 122 (e.g., by draining any residual charge in the floating diffusion node 122) prior to activation of the transfer gate 114 to transfer the photocurrent 110 from the photodiode 112 to the floating diffusion node 122.

The photocurrent 110 may be used to apply a floating diffusion voltage (V_{fd}) to a source follower gate 124 of the control circuitry region 108. This permits the photocurrent 110 to be observed without removing or discharging the photocurrent 110 from the floating diffusion node 122. The reset gate 118 may instead be used to remove or discharge the photocurrent 110 from the floating diffusion node 122.

The source follower gate 124 functions as a high impedance amplifier for the pixel sensor 100. The source follower gate 124 provides a voltage to current conversion of the floating diffusion voltage. The output of the source follower gate 124 is electrically connected with a row select gate 126, which is configured to control the flow of the photocurrent 110 to external circuitry. The row select gate 126 is controlled by selectively applying a select voltage (V_{di}) 128 to the gate of the row select gate 126. This permits the photocurrent 110 to flow to an output 130 of the pixel sensor 100.

As indicated above, FIG. 1 is provided as an example. Other examples may differ from what is described with regard to FIG. 1.

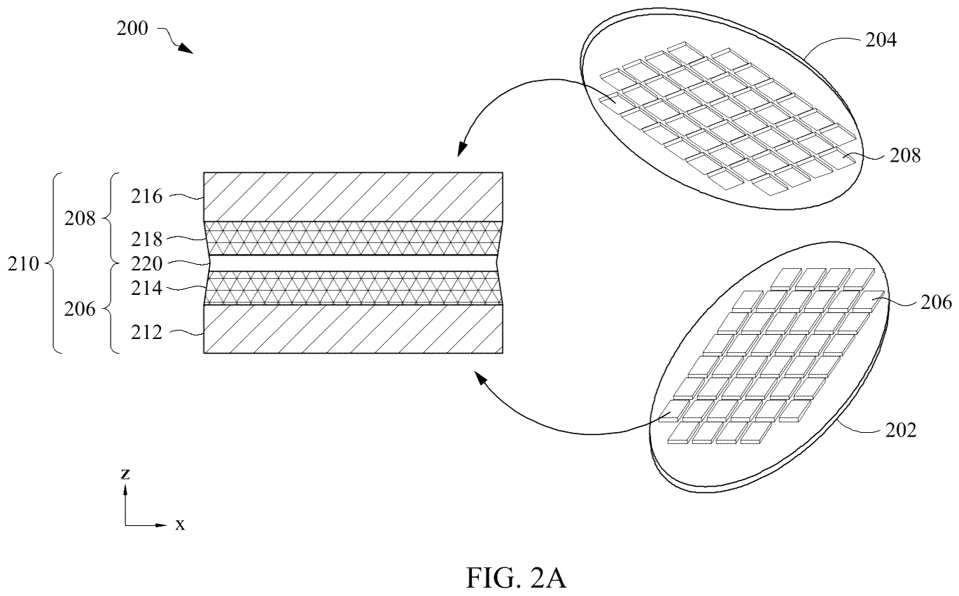

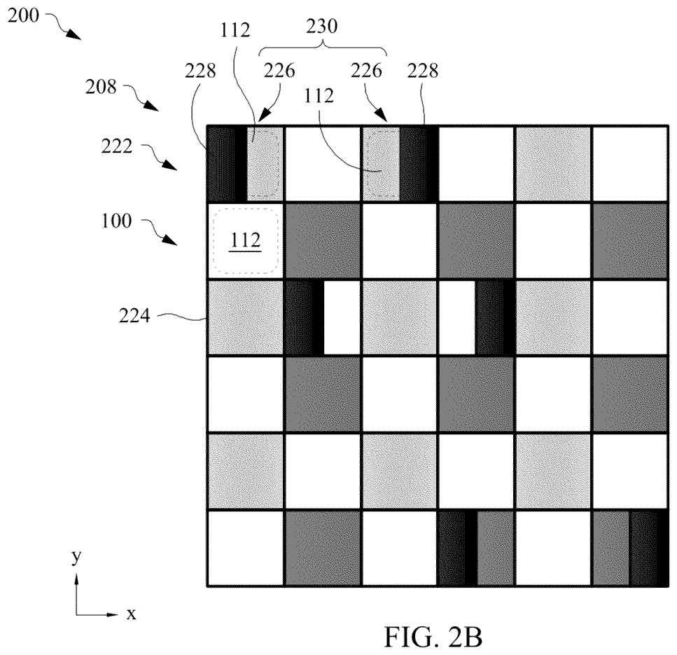

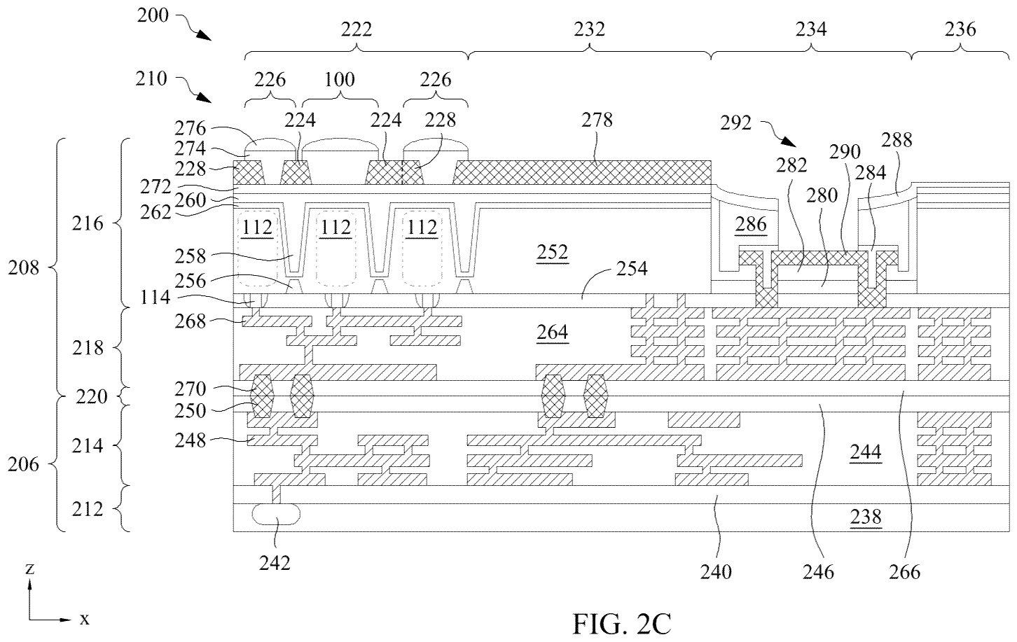

FIGS. 2A-2C are diagrams of examples 200 of an image sensor device described herein. As shown in FIG. 2A, an image sensor device may be formed by bonding a circuitry wafer 202 and a sensor wafer 204. For example, a bonding tool may be used to perform a bonding operation to bond the circuitry wafer 202 and the sensor wafer 204 using a metal-to-metal bonding technique, a dielectric-to-dielectric bonding technique, and/or another bonding technique. In the bonding operation, circuitry dies 206 on the circuitry wafer 202 are bonded with associated sensor dies 208 on the sensor wafer 204 to image sensor devices 210. The image sensor devices 210 are then diced and packaged. Other processing steps may be performed to form the image sensor devices 210.

Each image sensor device 210 includes a circuitry die 206 and a sensor die 208. The circuitry die 206 and the sensor die 208 may be stacked or vertically arranged in the image sensor device 210. The sensor die 208 includes a pixel sensor array that includes a plurality of pixel sensors 100, or portions of a plurality of pixel sensors 100. In particular, the pixel sensor array includes at least the sensing regions 106 (and thus, the photodiodes 112) of the pixel sensors 100. Accordingly, the sensor die 208 primarily is configured to sense photons of incident light and convert the photons to a photocurrent 110.

The circuitry die 206 includes circuitry that is configured to measure, manipulate, and/or otherwise use the photocurrent 110. Moreover, the circuitry die 206 includes at least a subset of the transistors of the control circuitry regions 108 of the pixel sensors 100. For example, the circuitry die 206 may include the row select gates 126 of the pixel sensors 100, the source follower gates 124 of the pixel sensor, and/or a combination thereof. This provides increased area on the sensor die 208 for the photodiodes 112, which enables the size of the photodiodes 112 to be increased to increase the sensitivity and/or overall performance of the light sensing performance of the pixel sensor, and/or enables the size of the pixel sensors 100 to be decreased while maintaining the same size for the photodiodes 112.

As further shown in FIG. 2A, the circuitry die 206 may include a device layer 212 and an interconnect layer 214. The device layer 212 may include the devices (e.g., transistors) of the circuitry die 206, and the interconnect layer 214 may include interconnects that enable signals and/or power to be provided to and/or from the devices in the device layer 212. The sensor die 208 may also include a device layer 216 and an interconnect layer 218. The device layer 216 may include portions of the pixel sensors 100, including the photodiodes 112, the transfer gates 114, and the floating diffusion nodes 122, among other examples. The interconnect layer 218 may include interconnects that enable signals and/or power to be provided to and/or from the device layer 216.

The circuitry die 206 and the sensor die 208 may be bonded at a bonding interface 220, which may be included between the interconnect layers 214 and 218, and/or may be included in a portion of the interconnect layers 214 and/or 218. The bonding interface 220 may include bonding pads, bonding vias, bonding dielectric layers, and/or other bonding structures.

FIG. 2B is a top-down view of an example pixel sensor array 222 included on a sensor die 208. The pixel sensor array 222 may be included on a sensor die 208 of an image sensor device 210. As shown in FIG. 2B, the pixel sensor array 222 may include a plurality of pixel sensors 100 (or portions of the plurality of pixel sensors 100). For example, the pixel sensor array 222 may include the photodiodes 112 of the pixel sensors 100. As further shown in FIG. 2B, the pixel sensors 100 may be arranged in a grid. In some implementations, the pixel sensors 100 are square-shaped (as shown in the example in FIG. 2B). In some implementations, the pixel sensors 100 include other shapes such as rectangle shapes, circle shapes, octagon shapes, diamond shapes, and/or other shapes.

In some implementations, the size of the pixel sensors 100 (e.g., the width or the diameter) of the pixel sensors 100 is approximately 1 micron. In some implementations, the size of the pixel sensors 100 (e.g., the width or the diameter) of the pixel sensors 100 is less than approximately 1 micron. For example, a width of one or more of the pixel sensors 100 may be included in a range of approximately 0.6 microns to approximately 0.7 microns. In these examples, the pixel sensors 100 may be referred to as sub-micron pixel sensors. Sub-micron pixel sensors may decrease the pixel sensor pitch (e.g., the distance between adjacent pixel sensors) in the pixel sensor array 222, which may enable increased pixel sensor density in the pixel sensor array 222 (which can increase the performance of the pixel sensor array 222). However, other values for the range of the size of the pixel sensors 100 are within the scope of the present disclosure.

Each pixel sensor 100 may be configured to sense a particular wavelength range of incident light associated with a particular color component of the incident light. For example, a pixel sensor 100 may be configured to sense a wavelength range associated with a red component of incident light, and may therefore be referred to as a red pixel sensor. As another example, a pixel sensor 100 may be configured to sense a wavelength range associated with a blue component of incident light, and may therefore be referred to as a blue pixel sensor. As another example, a pixel sensor 100 may be configured to sense a wavelength range associated with a green component of incident light, and may therefore be referred to as a green pixel sensor. In some implementations, a plurality of pixel sensors 100 are configured to sense a wavelength range associated with a near infrared (NIR) component of incident light, and may therefore be referred to as NIR pixel sensors. The NIR pixel sensors may be included in the pixel sensor array 222 to improve low-light performance of the image sensor device 210 and/or to enable night-vision functionality to be realized for the image sensor device 210.

As further shown in FIG. 2B, the photodiodes 112 of the pixel sensors 100 may be electrically and optically isolated by a metal grid structure 224 included in the pixel sensor array 222. The photodiodes 112 may be formed in a semiconductor layer (e.g., a substrate) of the sensor die 208, and the metal grid structure 224 may be included above the semiconductor layer. The metal grid structure 224 includes a plurality of intersecting metal lines around the perimeters of the pixel sensors 100. The metal grid structure 224 may be formed of tungsten (W) and/or another suitable metal or metal alloy. The metal grid structure 224 may be included in the pixel sensor array 222 to reduce optical cross-talk between the pixel sensors 100, which reduces color mixing between the pixel sensors 100.

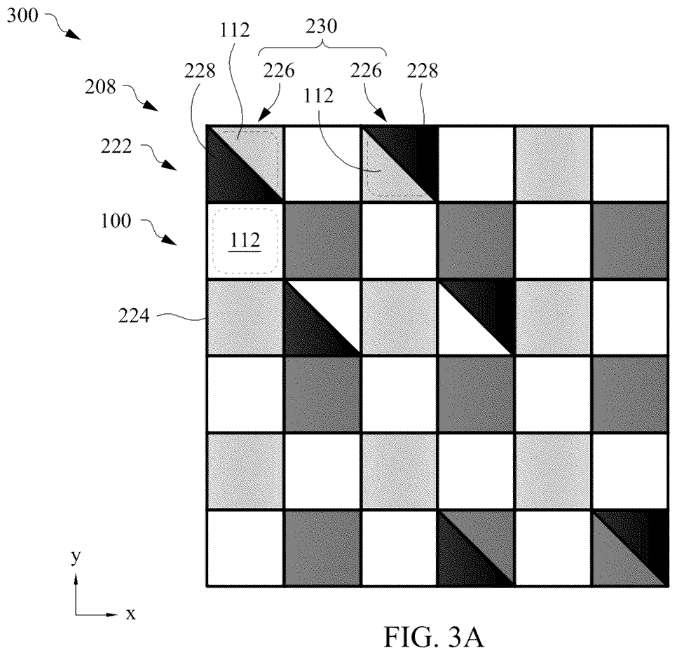

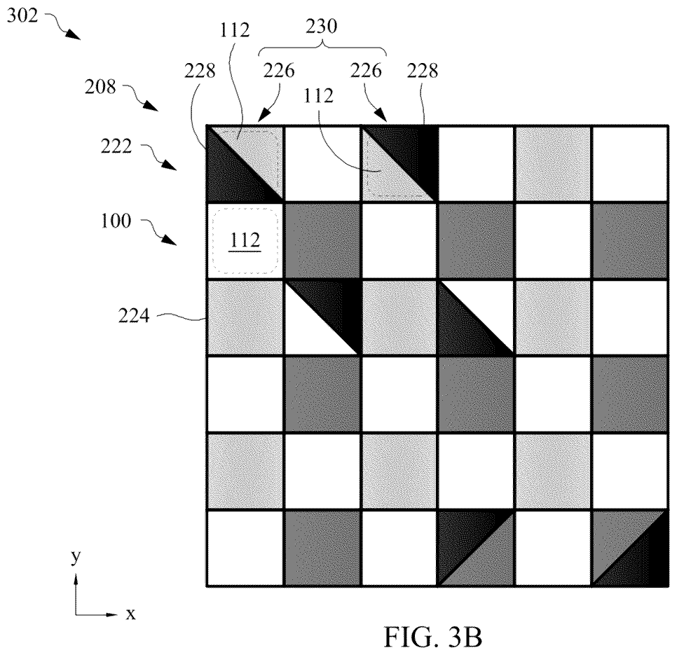

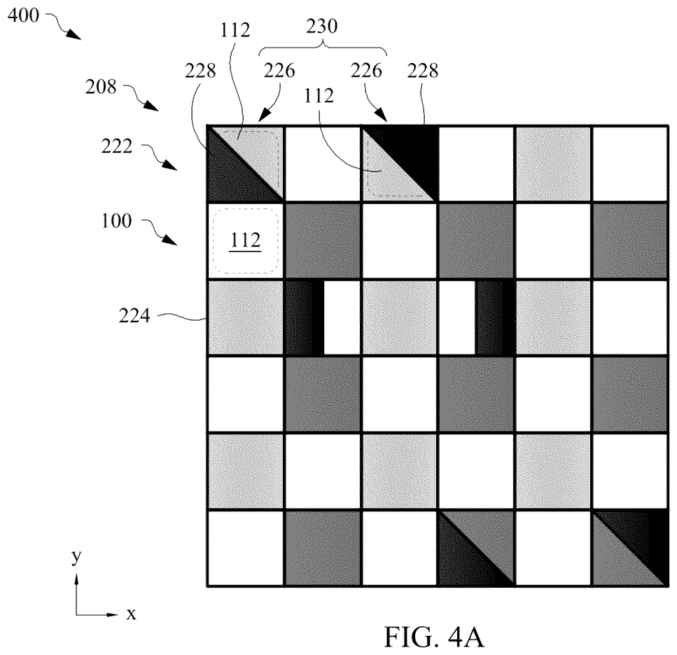

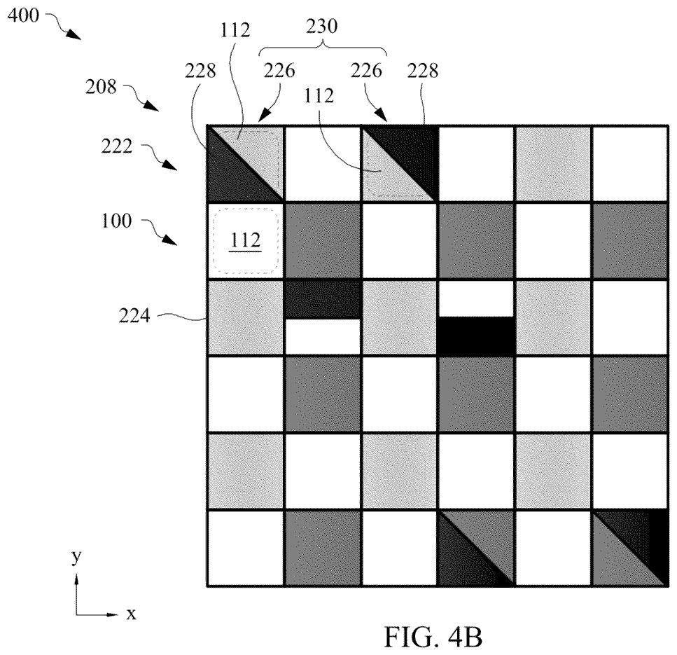

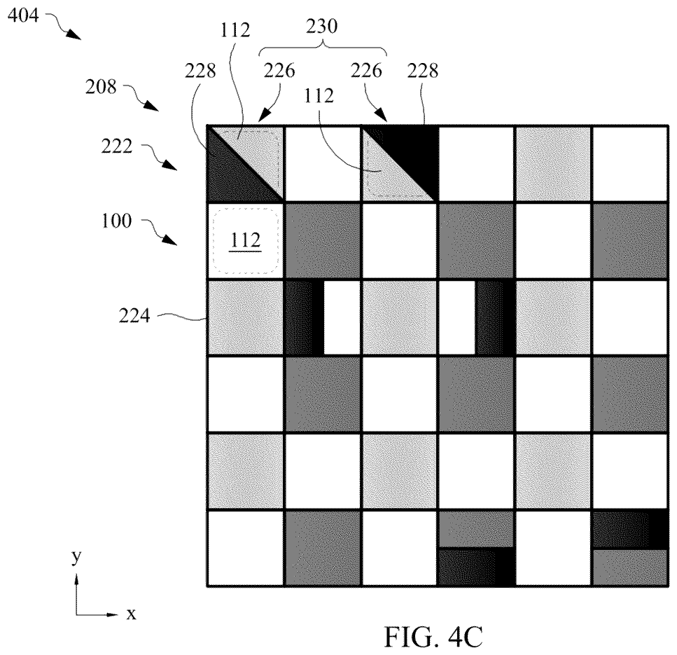

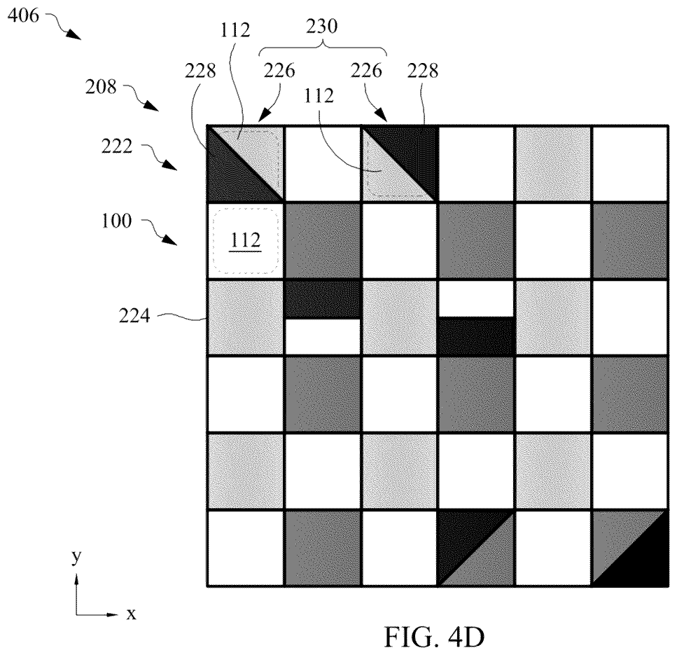

As further shown in FIG. 2B, the pixel sensor array 222 further includes autofocus pixel sensors 226. The autofocus pixel sensors 226 are similar to the pixel sensors 100, except that the autofocus pixel sensors 226 are configured to generate photocurrents 110 for the purpose of determining focus of the pixel sensor array 222, and the pixel sensors 100 are configured to generate photocurrents 110 for the purpose of generating an image or a video by the image sensor device 210. Structurally, the autofocus pixel sensors 226 differ from the pixel sensors 100 in that grid extensions 228 of the metal grid structure 224 extend over a portion of the tops of the photodiodes 112 of the autofocus pixel sensors 226. The grid extensions 228 are portions of the metal grid structure 224 that are formed during patterning of the metal grid structure 224. In particular, a mask in a patterning layer may be used to form grid extensions 228 during formation of the metal grid structure 224 such that the grid extensions 228 extend laterally outward from the metal grid structure 224 and over at least a portion of a plurality of the autofocus pixel sensors 226. As shown in FIG. 2B, the grid extensions 228 may have an approximately rectangular top view shape. However, other top view shapes are within the scope of the present disclosure, and other examples of top view shapes for the grid extensions 228 are illustrated and described in connection with FIGS. 3A, 3B, and/or one or more of FIGS. 4A-4D.

Autofocus pixel sensors 226 are arranged in autofocus pixel pairs 230, and the grid extensions 228 of the metal grid structure 224 cover opposing sides of the photodiodes 112 of the autofocus pixel sensors 226 in an autofocus pixel pair 230. For example, an autofocus pixel pair 230 may include a first autofocus pixel sensor 226 and a second autofocus pixel sensor 226. The first and second autofocus pixel sensors 226 may be formed with the same type of color filter and are thus configured to pass a same wavelength range. Therefore the autofocus pixel pair 230 may be configured to determine focus for a particular light component of incident light sensed by the pixel sensor array 222. In some implementations, the pixel sensor array 222 includes at least one autofocus pixel pair 230 for each of the color components for which the pixel sensor array 222 is configured to sense. For example, if the pixel sensor array 222 includes red pixel sensors 100, green pixel sensors 100, and blue pixel sensors 100, the pixel sensor array 222 may include red autofocus pixel pairs 230, green autofocus pixel pairs 230, and blue autofocus pixel pairs 230. This enables autofocus to be implemented for each of the color components of the pixel sensor array 222.

A first grid extension 228 may extend over and cover a left side of the top of the photodiode 112 of the first autofocus pixel sensor 226 such that a right side of the top of the photodiode 112 is exposed through the metal grid structure 224. A second grid extension 228 may extend over and cover a right side of the top of the photodiode 112 of the second autofocus pixel sensor 226 such that a left side of the top of the photodiode 112 is exposed through the metal grid structure 224. When incident light is received at the pixel sensor array 222, the incident light is sensed by the first and second autofocus pixel sensors 226 at opposing sides of the photodiodes 112 of the first and second autofocus pixel sensors 226 because of the arrangement of the first and second grid extensions 228. This results in a phase difference between the incident light sensed by the first autofocus pixel sensor 226 and the incident light sensed by the second autofocus pixel sensor 226. This phase difference is used (e.g., by the devices in the circuitry die 206) for determining the focus of the pixel sensor array. Thus, the grid extensions 228 and the autofocus pixel sensors 226 enable phase detection autofocus (PDAF) to be implemented “in-line” (e.g., integrated into) the pixel sensor array 222 (e.g., as opposed to having a separate PDAF region around the pixel sensor array 222 or adjacent to the pixel sensor array 222).

FIG. 2C illustrates a cross-section view of an image sensor device 210. As shown in FIG. 2C, a circuitry die 206 and a sensor die 208 may be bonded at a bonding interface 220 such that the circuitry die 206 and the sensor die 208 are stacked or vertically arranged in a z-direction in the image sensor device 210. As further shown in FIG. 2C, the image sensor device 210 includes the pixel sensor array 222 (e.g., including the pixel sensors 100 and the autofocus pixel sensors 226), a black level correction (BLC) region 232 adjacent to (e.g., horizontally adjacent to) the pixel sensor array 222, and a bonding pad region 234 adjacent to (e.g., horizontally adjacent to) the BLC region 232, and a seal ring region 236 adjacent to (e.g., horizontally adjacent to) the bonding pad region 234, among other examples.

As further shown in FIG. 2C, the image sensor device 210 includes a plurality of layers, such as the device layer 212 and the interconnect layer 214 of the circuitry die 206, and the device layer 216 and the interconnect layer 218 of the sensor die 208. The device layer 212 of the circuitry die 206 includes a semiconductor layer 238 and a dielectric layer 240 above the semiconductor layer 238. The semiconductor layer 238 may include silicon (Si) (e.g., a silicon substrate), a material including silicon, a III-V compound semiconductor material such as gallium arsenide (GaAs), a silicon on insulator (SOI), or another type of semiconductor material. The dielectric layer 406 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

Devices 242 may be included in and/or on the semiconductor layer 238 of the device layer 212. The devices 242 may include one or more application-specific integrated circuit (ASIC) devices, one or more system-on-chip (SOC) devices, one or more transistors, and/or one or more other components configured to measure the magnitude of a photocurrent 110 generated by the pixel sensors 100 to determine light intensity of incident light and/or to generate images and/or video (e.g., digital images, digital video). Moreover, the devices 242 may include one or more ASIC devices, one or more SOC devices, one or more transistors, and/or one or more other components configured to measure the magnitude of a photocurrent 110 generated by the autofocus pixel sensors 226 to determine a focus of the pixel sensor array 222.

The interconnect layer 214 of the circuitry die 206 may include a dielectric layer 244, a bonding layer 246, a plurality of interconnect structures 248 in the dielectric layer 244, and a plurality of bonding structures 250 in the bonding layer 246. The dielectric layer 244 may include one or more interlayer dielectric (ILD) layers, one or more intermetal dielectric (IMD) layers, and/or one or more etch stop layers (ESLs), among other examples. The dielectric layer 244 and the bonding layer 246 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 248 may each include conductive lines, trenches, vias, interconnects, metallization layers, and/or other types of electrically conductive structures that electrically connect the devices 242 to one or more other regions of the circuitry die 206 and/or to one or more regions of the sensor die 208, among other examples. The bonding structures 250 may each include bonding pads, bonding vias, and/or other types of bonding structures. The interconnect structures 248 and the bonding structures 250 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

The device layer 216 of the sensor die 208 includes a semiconductor layer 252 and a dielectric layer 254 below the semiconductor layer 252. The semiconductor layer 252 may include silicon (Si) (e.g., a silicon substrate), a material including silicon, a III-V compound semiconductor material such as gallium arsenide (GaAs), an SOI, or another type of semiconductor material. The dielectric layer 254 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The photodiodes 112 are included in the semiconductor layer 252 of the sensor die 208. The photodiodes 112 may each include one or more doped regions of semiconductor layer 252. The semiconductor layer 252 may be doped with a plurality of types of ions to form a p-n junction or a PIN junction (e.g., a junction between a p-type portion, an intrinsic (or undoped) type portion, and an n-type portion) corresponding to a photodiode 112. For example, the semiconductor layer 252 may be doped with an n-type dopant to form a first portion (e.g., an n-type portion) of a photodiode 112 and a p-type dopant to form a second portion (e.g., a p-type portion) of the photodiode 112. A photodiode 112 may be configured to absorb photons of incident light. The absorption of photons causes the photodiode 112 to accumulate a charge (a photocurrent 110) due to the photoelectric effect. Here, photons bombard the photodiode 112, which causes emission of electrons of the photodiode 112. The emission of electrons causes the formation of electron-hole pairs, where the electrons migrate toward the cathode of the photodiode 112 and the holes migrate toward the anode, which produces the photocurrent 110.

The photodiodes 112 may be electrically isolated and/or optically isolated from one another by one or more isolation structures in the semiconductor layer 252. Shallow trench isolation (STI) structures 256 extend into the semiconductor layer 252 from a bottom side of the semiconductor layer 252 (referred to as the front side of the semiconductor layer 252), and a deep trench isolation (DTI) structure 258 extends into the semiconductor layer 252 from a top side of the semiconductor layer 252 (referred to as the back side of the semiconductor layer 252) over the STI structures 256. The combination of the STI structures 256 and the DTI structure 258 in the semiconductor layer 252 surround the pixel sensors 100 and autofocus pixel sensors 226 in the semiconductor layer 252 and provide the electrically isolation and/or optically isolation for the pixel sensors 100 and autofocus pixel sensors 226 in the semiconductor layer 252.

The STI structures 256 may include one or more dielectric materials, such as a silicon oxide (SiOₓ), a silicon nitride (SiₓN_{y}), and/or a silicon oxynitride (SiON), among other examples. The DTI structure 258 may include elongated structures of dielectric material 260 and a dielectric liner 262 between the dielectric material 260 and the semiconductor layer 252. The DTI structure 258 extends along the sides of the photodiodes 112 and conforms to the top view shape of the metal grid structure 224 (not including the grid extensions 228) illustrated in FIG. 2B. The dielectric material 260 may also be included on the top side of the semiconductor layer 252 as a buffer layer. The dielectric liner 262 may be included on sidewalls and on a bottom surface of the DTI structure 258, and may be included as an antireflective coating (ARC) and/or to further facilitate electrical and/or optical isolation of the pixel sensors 100 and autofocus pixel sensors 226. In some implementations, the dielectric material 260 includes a silicon oxide (SiOₓ) (e.g., silicon dioxide (SiO₂)), a silicon nitride (SiₓN_{y}), a silicon carbide (SiCₓ), a hafnium oxide (HfOₓ), a silicon oxynitride (SiON), tetraethyl orthosilicate oxide, phosphosilicate glass (PSG), borophosphosilicate glass (BPSG), fluorinated silica glass (FSG), carbon doped silicon oxide, and/or another dielectric material. In some implementations, the dielectric liner 262 may include a high-k dielectric material such as a silicon nitride (SiₓN_{y}), a hafnium oxide (HfOₓ), and/or another high-k dielectric material.

Transfer gates 114 are included in the dielectric layer 254 and on the bottom side of the semiconductor layer 252. The transfer gates 114 are electrically connected to the interconnect layer 218, which enables inputs (e.g., gate voltages) to be provided to the transfer gates 114. The interconnect layer 218 may include a dielectric layer 264, a bonding layer 266, a plurality of interconnect structures 268 in the dielectric layer 264, and a plurality of bonding structures 270 in the bonding layer 266. The dielectric layer 264 may include one or more ILD layers, one or more IMD layers, and/or one or more ESLs, among other examples. The dielectric layer 264 and the bonding layer 266 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples.

The interconnect structures 268 may each include conductive lines, trenches, vias, interconnects, metallization layers, and/or other types of electrically conductive structures that electrically connect the transfer gates 114 to one or more other regions of the sensor die 208 and/or to one or more regions of the circuitry die 206, among other examples. The bonding structures 270 may each include bonding pads, bonding vias, and/or other types of bonding structures. The interconnect structures 268 and the bonding structures 270 may each include one or more electrically conductive materials, such as, an electrically conductive metal, an electrically conductive metal alloy, an electrically conductive ceramic, tungsten (W), cobalt (Co), ruthenium (Ru), titanium (Ti), aluminum (Al), copper (Cu), and/or gold (Au), among other examples of electrically conductive materials.

At the bonding interface 220, the bonding layers 246 and 266 may be bonded together (e.g., in a dielectric-to-dielectric bond), and the bonding structures 250 and 270 may be bonded together (e.g., in a metal-to-metal bond). Signals and/or power may be provided between the circuitry die 206 and the sensor die 208 through the bonding structures 250 and 270.

Above the top side of the semiconductor layer 252, a passivation layer 272 may be included on the buffer layer, and the metal grid structure 224 and associated grid extensions 228 may be included above the passivation layer 272. The passivation layer 272 may include an oxide material such as a silicon oxide (SiOₓ). Additionally and/or alternatively, a silicon nitride (SiNₓ), a silicon carbide (SiCₓ), or a mixture thereof, such as a silicon carbon nitride (SiCN), a silicon oxynitride (SiON), or another dielectric material is used for the passivation layer 272.

As shown in FIG. 2C, the grid extensions 228 may laterally extend outward (e.g., in the x-direction) from the metal grid structure 224 and over portions of the photodiodes 112 of the autofocus pixel sensors 226. The metal grid structure 224 and the associated grid extensions 228 may include columns or pillars surrounding the photodiodes 112. The columns or pillars of the metal grid structure 224 and associated grid extensions 228 may be located over the DTI structure 258. The metal grid structure 224 and associated grid extensions 228 may be formed of a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

Color filter regions 274 of the pixel sensors 100 be included in openings in the metal grid structure 224. The color filter regions 274 may be included above the photodiodes 112 of the pixel sensors 100. Color filter regions 274 of the autofocus pixel sensors 226 be included in openings between the metal grid structure 224 and grid extensions 228. The color filter regions 274 may be included above the photodiodes 112 of the autofocus pixel sensors 226.

Each color filter region 274 may be configured to filter incident light to allow a particular wavelength of the incident light to pass to a photodiode 112. For example, a color filter region 274 may filter incident light to allow red light to pass through the color filter region 274 to an associated photodiode 112. As another example, a color filter region 274 may filter incident light to allow green light to pass through the color filter region 274 to an associated photodiode 112. As another example, a color filter region 274 may filter incident light to allow blue light to pass through the color filter region 274 to an associated photodiode 112.

A blue color filter region 274 may permit the component of incident light near a 450 nanometer wavelength to pass through and may block other wavelengths from passing. A green color filter region 274 may permit the component of incident light near a 550 nanometer wavelength to pass and may block other wavelengths from passing. A red color filter region 274 may permit the component of incident light near a 650 nanometer wavelength to pass and may block other wavelengths from passing. A yellow color filter region 274 may permit the component of incident light near a 580 nanometer wavelength to pass and may block other wavelengths from passing.

In some implementations, a color filter region 274 may be non-discriminating or non-filtering, which may define a white pixel sensor. A non-discriminating or non-filtering color filter region 274 may include a material that permits all wavelengths of light to pass into the associated photodiode 112 (e.g., for purposes of determining overall brightness to increase light sensitivity for the image sensor). In some implementations, a color filter region 274 may be a an NIR bandpass color filter region 274, which may define an NIR pixel sensor. An NIR bandpass color filter region 274 may include a material that permits the portion of incident light in an NIR wavelength range to pass to an associated photodiode 112 while blocking visible light from passing.

Micro-lenses 276 may be included over and/or on the color filter regions 274. The micro-lenses 276 may include a respective micro-lens for each of the pixel sensors 100 and autofocus pixel sensors 226. A micro-lens may be formed to focus incident light toward a photodiode 112 of an associated pixel sensor 100 or autofocus pixel sensor 226.

As further shown in FIG. 2C, a metal layer 278 may be included above the semiconductor layer 252 in the BLC region 232 of the semiconductor layer 252. The metal layer 278 may be included as a light-blocking layer to prevent incident light from entering the portion of semiconductor layer 252 in the BLC region 232. The portion of semiconductor layer 252 in the BLC region 232 is thus a sensing region that is kept “dark” so that dark current measurements may be performed in the BLC region 232. A dark current measurement may be performed to measure the amount of charge (dark current) in the semiconductor layer 252 that is generated from sources other than incident light (e.g., from thermal energy in the semiconductor layer 252) so that the dark current measurement may be used for black level correction (or black level calibration) for the pixel sensor array 222.

As further shown in FIG. 2C, the bonding pad region 234 may include a plurality of dielectric layers 280, 282, 284, 286, and 288 that electrically isolate a bonding pad structure 290. The bonding pad structure 290 is electrically coupled and/or physically coupled with one or more of the interconnect structures 268 in the interconnect layer 218 of the sensor die 208. A bonding pad opening 292 is included above the bonding pad structure 290 to enable an external electrical connection to be formed to the bonding pad structure 290.

The plurality of dielectric layers 280, 282, 284, 286, and 288 may each include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silica glass (FSG), and/or carbon doped silicon oxide, among other examples. The bonding pad structure 290 may include a metal material, such as gold (Au), copper (Cu), silver (Ag), cobalt (Co), tungsten (W), titanium (Ti), ruthenium (Ru), a metal alloy (e.g., aluminum copper (AlCu)), and/or a combination thereof, among other examples.

The seal ring region 236 includes a plurality of stacked interconnect structures 248 in the interconnect layer 214 and a plurality of stacked interconnect structures 268 in the interconnect layer 218 to seal the structures and layers of the image sensor device 210 to prevent ingress of humidity and other contaminants, as well as to provide structural rigidity to the image sensor device 210.

As indicated above, FIGS. 2A-2C are provided as examples. Other examples may differ from what is described with regard to FIGS. 2A-2C.

FIG. 3A are diagram of examples of pixel sensor arrays 222 of a sensor die 208 described herein. FIG. 3A illustrates a top view of an example 300 of a pixel sensor array 222. As shown in FIG. 3A, the example 300 of the pixel sensor array 222 is similar to the example 200 of a pixel sensor array 222 illustrated in FIG. 2B. However, the example 300 of the pixel sensor array 222 includes grid extensions 228 that have an approximately triangular top view shape as opposed to the approximately rectangular top view shape illustrated in FIG. 2B. Thus, autofocus pixel pairs 230 include autofocus pixel sensors 226 for which grid extensions 228 cover opposing diagonal portions (e.g., opposing corners) of the photodiodes 112 of the autofocus pixel sensors 226.

FIG. 3B illustrates a top view of an example 302 of a pixel sensor array 222. As shown in FIG. 3B, the example 302 of the pixel sensor array 222 is similar to the example 300 of a pixel sensor array 222 illustrated in FIG. 3A. However, in the example 302 of the pixel sensor array 222, the grid extensions 228 are mirrored for two or more autofocus pixel pairs 230. For example, a first autofocus pixel pair 230 may have grid extensions 228 in the southwest quadrant of a first autofocus pixel sensor 226 and in the northeast quadrant of a second autofocus pixel sensor 226 in the x-y plane, and a second autofocus pixel pair 230 may have grid extensions 228 in the northeast quadrant of a first autofocus pixel sensor 226 and in the southwest quadrant of a second autofocus pixel sensor 226 in the x-y plane.

Additionally and/or alternatively, in the example 302 of the pixel sensor array 222, the grid extensions 228 of a first autofocus pixel pair 230 are orientated 90 degrees relative to a second autofocus pixel pair 230. For example, the first autofocus pixel pair 230 may have grid extensions 228 in the southwest quadrant of a first autofocus pixel sensor 226 and in the northeast quadrant of a second autofocus pixel sensor 226 in the x-y plane, and a second autofocus pixel pair 230 may have grid extensions 228 in the northwest quadrant of a first autofocus pixel sensor 226 and in the southeast quadrant of a second autofocus pixel sensor 226 in the x-y plane.

As indicated above, FIGS. 3A and 3B are provided as examples. Other examples may differ from what is described with regard to FIGS. 3A and 3B.

FIGS. 4A-4D are diagrams of examples of pixel sensor arrays 222 of a sensor die 208 described herein. FIG. 4A illustrates a top view of an example 400 of a pixel sensor array 222. As shown in FIG. 4A, the example 400 of the pixel sensor array 222 is similar to the example 200 of a pixel sensor array 222 illustrated in FIG. 2B. However, the example 400 of the pixel sensor array 222 includes grid extensions 228 that have an approximately triangular top view shape in addition to grid extensions 228 that have an approximately rectangular top view shape.

FIG. 4B illustrates a top view of an example 402 of the pixel sensor array 222. As shown in FIG. 4B, the example 402 of the pixel sensor array 222 is similar to the example 400 of a pixel sensor array 222 illustrated in FIG. 4A. However, in the example 402 of the pixel sensor array 222, the grid extensions 228 that have the approximately rectangular top view shape are rotated approximately 90 degrees relative to the example 400 of the pixel sensor array.

FIG. 4C illustrates a top view of an example 404 of the pixel sensor array 222. As shown in FIG. 4C, the example 404 of the pixel sensor array 222 is similar to the example 400 of a pixel sensor array 222 illustrated in FIG. 4A. However, in the example 404 of the pixel sensor array 222, a plurality of autofocus pixel pairs 230 include grid extensions 228 that have the approximately rectangular top view shapes, where a first autofocus pixel pair 230 includes grid extensions 228 that have the approximately rectangular top view shapes that are rotated approximately 90 degrees relative to a second autofocus pixel pair 230 that includes grid extensions 228 that have the approximately rectangular top view shapes. Thus, the grid extensions 228 for the first autofocus pixel pair 230 are orthogonal to the grid extensions 228 for the second autofocus pixel pair 230.

FIG. 4D illustrates a top view of an example 406 of the pixel sensor array 222. As shown in FIG. 4D, the example 406 of the pixel sensor array 222 is similar to the example 400 of a pixel sensor array 222 illustrated in FIG. 4A. However, in the example 406 of the pixel sensor array 222, a plurality of autofocus pixel pairs 230 include grid extensions 228 that have the approximately triangular top view shapes, where a first autofocus pixel pair 230 includes grid extensions 228 that have the approximately triangular top view shapes that are rotated approximately 90 degrees relative to a second autofocus pixel pair 230 that includes grid extensions 228 that have the approximately triangular top view shapes.

As indicated above, FIGS. 4A-4D are provided as examples. Other examples may differ from what is described with regard to FIGS. 4A-4D. The example top view configurations illustrated in FIGS. 3A, 3B, and/or 4A-4D may be implemented in an image sensor device 210 for particular use cases. For example, one or more of top view configurations illustrated in FIGS. 3A, 3B, and/or 4A-4D may be implemented in an image sensor device 210 depending on the estimated angle or direction of incident light in the use case or application for the image sensor device 210. For example, a top view configuration for an image sensor device 210 with a security camera use case may be different from a top view configuration for an image sensor device 210 with an automotive camera use case in that images and/or video are to be captured at different angles for these use cases.

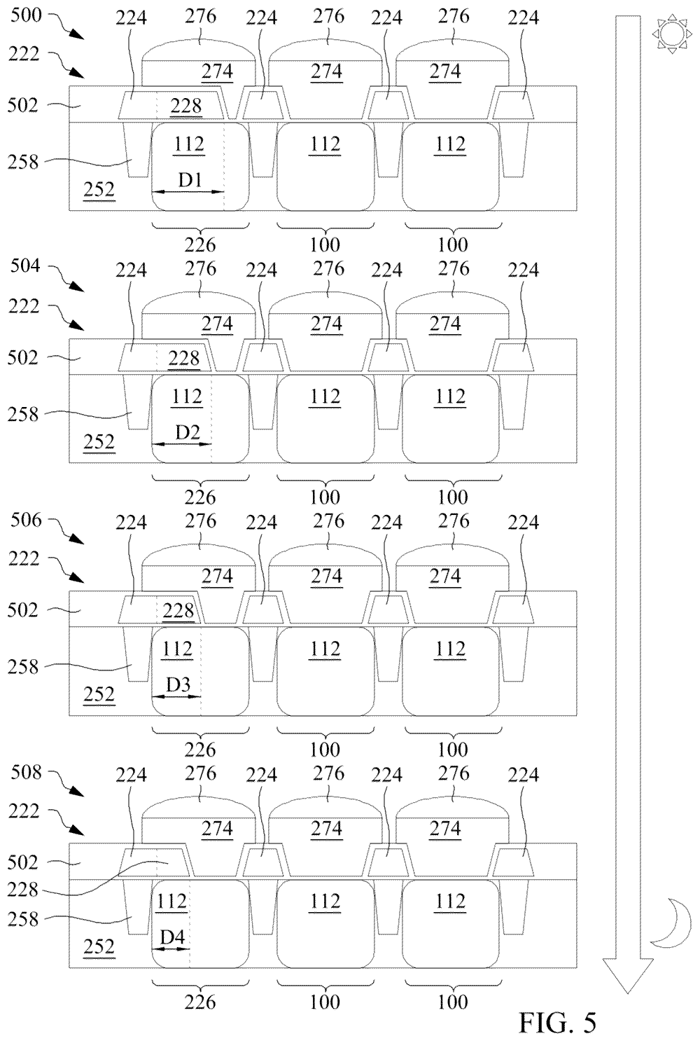

FIG. 5 is a diagram of examples of pixel sensor arrays 222 of a sensor die 208 described herein. FIG. 5 illustrates cross-section views of the examples of the pixel sensor arrays 222. The examples illustrated in FIG. 5 correspond to different sizes and/or different amount of coverage of the photodiodes 112 of autofocus pixel sensors 226 included in the examples of the pixel sensor arrays 222.

As shown in FIG. 5, an example 500 of a pixel sensor array 222 includes one or more pixel sensors 100 and one or more autofocus pixel sensors 226. The pixel sensor(s) 100 and the autofocus pixel sensor(s) 226 each include a photodiode 112 in the semiconductor layer 252 of the sensor die 208. A DTI structure 258 is included around the photodiodes 112 in the semiconductor layer 252, and a metal grid structure 224 is included on the semiconductor layer 252 above the DTI structure 258. The metal grid structure 224 extends above the semiconductor layer 252 and surrounds the photodiodes 112. Color filter regions 274 are included between the openings of the metal grid structure 224, and micro-lenses 276 are included on the color filter regions. A passivation layer 502 additionally be included on the metal grid structure 224, or may be omitted.

As further shown in the example 500, a grid extension 228 extends laterally outward from the metal grid structure 224 and over a portion of the photodiode 112 of an autofocus pixel sensor 226. The grid extension 228 extends laterally outward from the metal grid structure 224 by a distance D1 such that the portion of the photodiode 112 is shielded from incident light.

As shown in an example 504 of a pixel sensor array 222 in FIG. 5, a grid extension 228 extends laterally outward from the metal grid structure 224 and over a portion of the photodiode 112 of an autofocus pixel sensor 226. The grid extension 228 extends laterally outward from the metal grid structure 224 by a distance D2 in the example 504, where the distance D2 is less than the distance D1. Thus, for the same sized photodiode 112, less of the top area of the photodiode 112 of the autofocus pixel sensor 226 in the example 504 of the pixel sensor array 222 is covered by a grid extension 228 than in the example 500 of a pixel sensor array 222. Accordingly, a greater amount of incident light may pass through to the photodiode 112 of the autofocus pixel sensor 226 in the example 504 of the pixel sensor array 222 than for the photodiode 112 of the autofocus pixel sensor 226 in the example 500 of the pixel sensor array 222.

As shown in an example 506 of a pixel sensor array 222 in FIG. 5, a grid extension 228 extends laterally outward from the metal grid structure 224 and over a portion of the photodiode 112 of an autofocus pixel sensor 226. The grid extension 228 extends laterally outward from the metal grid structure 224 by a distance D3 in the example 506, where the distance D3 is less than the distances D1 and D2. Thus, for the same sized photodiode 112, less of the top area of the photodiode 112 of the autofocus pixel sensor 226 in the example 506 of the pixel sensor array 222 is covered by a grid extension 228 than in the examples 500 and 504. Accordingly, a greater amount of incident light may pass through to the photodiode 112 of the autofocus pixel sensor 226 in the example 506 than for the examples 500 and 504.

As shown in an example 508 of a pixel sensor array 222 in FIG. 5, a grid extension 228 extends laterally outward from the metal grid structure 224 and over a portion of the photodiode 112 of an autofocus pixel sensor 226. The grid extension 228 extends laterally outward from the metal grid structure 224 by a distance D4 in the example 508, where the distance D4 is less than the distances D1-D3. Thus, for the same sized photodiode 112, less of the top area of the photodiode 112 of the autofocus pixel sensor 226 in the example 508 of the pixel sensor array 222 is covered by a grid extension 228 than in the examples 500, 504, and 506. Accordingly, a greater amount of incident light may pass through to the photodiode 112 of the autofocus pixel sensor 226 in the example 508 than for the examples 500, 504, and 506.

The greater the amount of coverage of a photodiode 112 of an autofocus pixel sensor 226 by a grid extension 228, the less full well capacity (FWC) the autofocus pixel sensor 226 has. Thus, the autofocus pixel sensor 226 in the example 508 may have a greater FWC than the autofocus pixel sensor 226 in the example 506, the autofocus pixel sensor 226 in the example 506 may have a greater FWC than the autofocus pixel sensor 226 in the example 504, and the autofocus pixel sensor 226 in the example 504 may have a greater FWC than the autofocus pixel sensor 226 in the example 500. The autofocus pixel sensors 226 that have greater FWC may have greater autofocus performance in low light scenarios (such as in night vision use cases) in that the greater FWC enables the autofocus pixel sensors 226 to absorb a greater amount of incident light for determining the focus of the pixel sensor arrays 222. Conversely, in well-lit scenarios (such as in daytime use cases), less FWC is needed, and the autofocus pixel sensors 226 that have less FWC may have faster incident light detection, thereby enabling fast autofocus performance in well-lit scenarios.

As further shown in FIG. 5, the metal grid structures 224 and the associated grid extensions 228 in the examples 500, 504, 506, and 508 may have an approximately trapezoidal cross-section shape or profile. For example, a cross-sectional width of a top surface of the metal grid structures 224 and the associated grid extensions 228 in the examples 500, 504, 506, and 508 may be less than a cross-sectional width of a bottom surface of the metal grid structures 224 and the associated grid extensions 228 in the examples 500, 504, 506, and 508. Thus, the cross-sectional width increases from the top surface to the bottom surface for the metal grid structures 224 and the associated grid extensions 228 in the examples 500, 504, 506, and 508.

As indicated above, FIG. 5 is provided as examples. Other examples may differ from what is described with regard to FIG. 5.

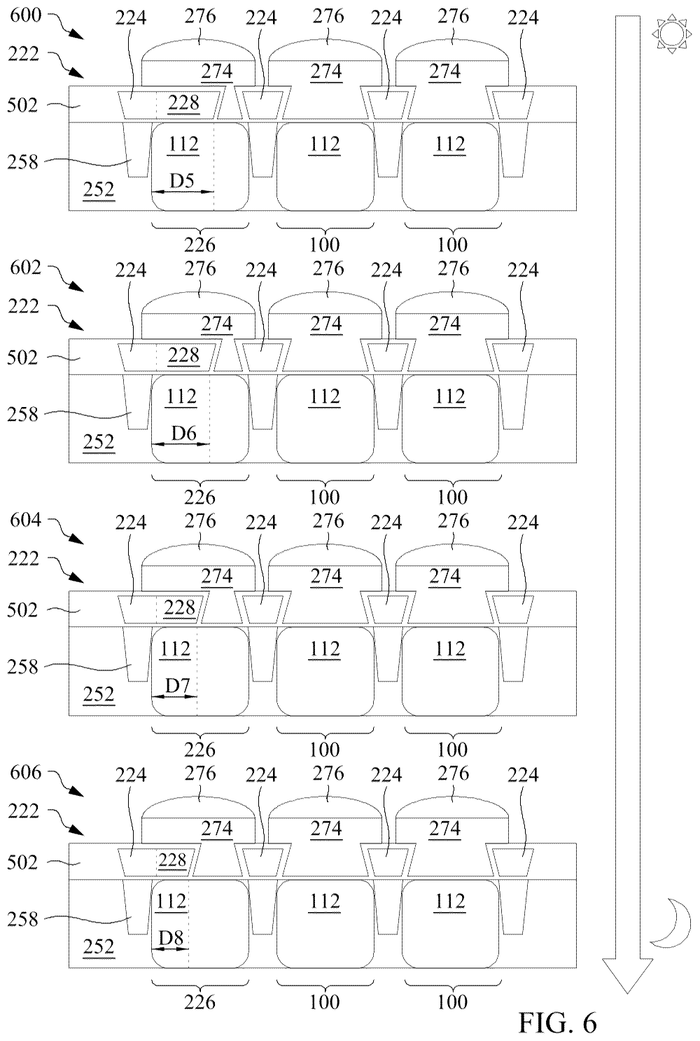

FIG. 6 is a diagram of examples of pixel sensor arrays 222 of a sensor die 208 described herein. FIG. 6 illustrates cross-section views of the examples of the pixel sensor arrays 222. The examples illustrated in FIG. 6 correspond to different sizes and/or different amount of coverage of the photodiodes 112 of autofocus pixel sensors 226 included in the examples of the pixel sensor arrays 222.

As shown in FIG. 6, an example 600 of a pixel sensor array 222 includes one or more pixel sensors 100 and one or more autofocus pixel sensors 226. The pixel sensor(s) 100 and the autofocus pixel sensor(s) 226 each include a photodiode 112 in the semiconductor layer 252 of the sensor die 208. A DTI structure 258 is included around the photodiodes 112 in the semiconductor layer 252, and a metal grid structure 224 is included on the semiconductor layer 252 above the DTI structure 258. The metal grid structure 224 extends above the semiconductor layer 252 and surrounds the photodiodes 112. Color filter regions 274 are included between the openings of the metal grid structure 224, and micro-lenses 276 are included on the color filter regions. A passivation layer 502 additionally be included on the metal grid structure 224, or may be omitted.

As further shown in the example 600, a grid extension 228 extends laterally outward from the metal grid structure 224 and over a portion of the photodiode 112 of an autofocus pixel sensor 226. The grid extension 228 extends laterally outward from the metal grid structure 224 by a distance D5 such that the portion of the photodiode 112 is shielded from incident light.

As shown in an example 602 of a pixel sensor array 222 in FIG. 6, a grid extension 228 extends laterally outward from the metal grid structure 224 and over a portion of the photodiode 112 of an autofocus pixel sensor 226. The grid extension 228 extends laterally outward from the metal grid structure 224 by a distance D6 in the example 602, where the distance D6 is less than the distance D5. Thus, for the same sized photodiode 112, less of the top area of the photodiode 112 of the autofocus pixel sensor 226 in the example 602 of the pixel sensor array 222 is covered by a grid extension 228 than in the example 600 of a pixel sensor array 222. Accordingly, a greater amount of incident light may pass through to the photodiode 112 of the autofocus pixel sensor 226 in the example 602 of the pixel sensor array 222 than for the photodiode 112 of the autofocus pixel sensor 226 in the example 600 of the pixel sensor array 222.

As shown in an example 604 of a pixel sensor array 222 in FIG. 6, a grid extension 228 extends laterally outward from the metal grid structure 224 and over a portion of the photodiode 112 of an autofocus pixel sensor 226. The grid extension 228 extends laterally outward from the metal grid structure 224 by a distance D7 in the example 604, where the distance D7 is less than the distances D5 and D6. Thus, for the same sized photodiode 112, less of the top area of the photodiode 112 of the autofocus pixel sensor 226 in the example 604 of the pixel sensor array 222 is covered by a grid extension 228 than in the examples 600 and 602. Accordingly, a greater amount of incident light may pass through to the photodiode 112 of the autofocus pixel sensor 226 in the example 604 than for the examples 600 and 602.

As shown in an example 606 of a pixel sensor array 222 in FIG. 6, a grid extension 228 extends laterally outward from the metal grid structure 224 and over a portion of the photodiode 112 of an autofocus pixel sensor 226. The grid extension 228 extends laterally outward from the metal grid structure 224 by a distance D8 in the example 606, where the distance D8 is less than the distances D5-D7. Thus, for the same sized photodiode 112, less of the top area of the photodiode 112 of the autofocus pixel sensor 226 in the example 606 of the pixel sensor array 222 is covered by a grid extension 228 than in the examples 600, 602, and 604. Accordingly, a greater amount of incident light may pass through to the photodiode 112 of the autofocus pixel sensor 226 in the example 606 than for the examples 600, 602, and 604.

The greater the amount of coverage of a photodiode 112 of an autofocus pixel sensor 226 by a grid extension 228, the less full well capacity (FWC) the autofocus pixel sensor 226 has. Thus, the autofocus pixel sensor 226 in the example 606 may have a greater FWC than the autofocus pixel sensor 226 in the example 606, the autofocus pixel sensor 226 in the example 604 may have a greater FWC than the autofocus pixel sensor 226 in the example 604, and the autofocus pixel sensor 226 in the example 604 may have a greater FWC than the autofocus pixel sensor 226 in the example 600. The autofocus pixel sensors 226 that have greater FWC may have greater autofocus performance in low light scenarios (such as in night vision use cases) in that the greater FWC enables the autofocus pixel sensors 226 to absorb a greater amount of incident light for determining the focus of the pixel sensor arrays 222. Conversely, in well-lit scenarios (such as in daytime use cases), less FWC is needed, and the autofocus pixel sensors 226 that have less FWC may have faster incident light detection, thereby enabling fast autofocus performance in well-lit scenarios.

As further shown in FIG. 6, the metal grid structures 224 and the associated grid extensions 228 in the examples 600, 602, 604, and 606 may have an approximately inverted trapezoidal cross-section shape or profile. For example, a cross-sectional width of a top surface of the metal grid structures 224 and the associated grid extensions 228 in the examples 600, 602, 604, and 606 may be greater than a cross-sectional width of a bottom surface of the metal grid structures 224 and the associated grid extensions 228 in the examples 600, 602, 604, and 606. Thus, the cross-sectional width decreases from the top surface to the bottom surface for the metal grid structures 224 and the associated grid extensions 228 in the examples 600, 602, 604, and 606.

As indicated above, FIG. 6 is provided as examples. Other examples may differ from what is described with regard to FIG. 6.

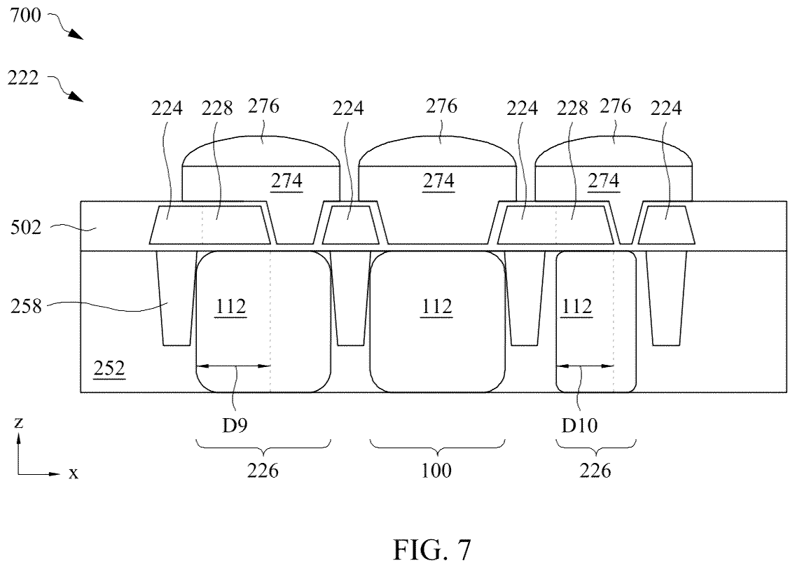

FIG. 7 is a diagram of an example 700 of a pixel sensor array 222 of a sensor die 208 described herein. FIG. 7 illustrates cross-section views of the example 700 of the pixel sensor array 222. In the example 700, the pixel sensor array 222 includes autofocus pixel sensors 226 for which different amount of the associated photodiodes 112 are covered by grid extensions 228 of the metal grid structure 224. For example, a first autofocus pixel sensor 226 in the pixel sensor array 222 includes a first photodiode 112 for which a first grid extension 228 extends laterally over the top of the first photodiode 112 by a distance D9. A second autofocus pixel sensor 226 in the pixel sensor array 222 includes a second photodiode 112 for which a second grid extension 228 extends laterally over the top of the second photodiode 112 by a distance D10 that is greater than the distance D9. If the first and second photodiodes 112 have approximately a same cross-sectional width, a greater amount of the area of the second photodiode 112 is shielded from incident light than the first photodiode 112. Thus, the first photodiode 112 may have greater FWC than the second photodiode 112, which means that the first autofocus pixel sensor 226 may have greater low-light performance than the second autofocus pixel sensor 226. Conversely, the lesser FWC of the second photodiode 112 may enable the second photodiode 112 to more quickly generate a photocurrent 110 than the first photodiode 112 in well-lit scenarios, meaning that the second autofocus pixel sensor 226 may have faster autofocus performance in well-lit scenarios than the first autofocus pixel sensor 226.

Including the first autofocus pixel sensor 226 and the second autofocus pixel sensor 226 in the same pixel sensor array 222 enables high autofocus performance to be achieved in different illumination scenarios. The greater FWC of the first autofocus pixel sensor 226 enables high autofocus performance to be achieved in low-light scenarios, whereas the lesser FWC of the second autofocus pixel sensor 226 enables high autofocus performance to be achieved in well-lit scenarios.

As further shown in FIG. 7, the metal grid structures 224 and the associated grid extensions 228 over the autofocus pixel sensors 226 may have an approximately trapezoidal cross-section shape or profile. For example, a cross-sectional width of a top surface of the metal grid structures 224 and the associated grid extensions 228 may be less than a cross-sectional width of a bottom surface of the metal grid structures 224 and the associated grid extensions 228. Thus, the cross-sectional width increases from the top surface to the bottom surface for the metal grid structures 224 and the associated grid extensions 228.

As indicated above, FIG. 7 is provided as examples. Other examples may differ from what is described with regard to FIG. 7.

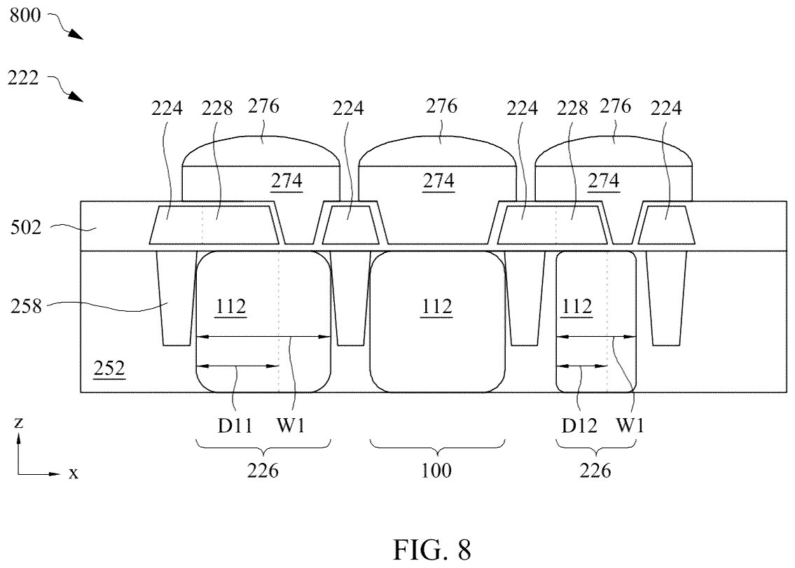

FIG. 8 is a diagram of an example 800 of a pixel sensor array 222 of a sensor die 208 described herein. FIG. 8 illustrates cross-section views of the example 800 of the pixel sensor array 222. In the example 800, the pixel sensor array 222 includes autofocus pixel sensors 226 that have photodiodes 112 of different cross-sectional widths. For example, a first autofocus pixel sensor 226 may have a first photodiode 112 with a first cross-sectional width W1 that is greater than a second cross-sectional width W2 of a second photodiode 112 of a second autofocus pixel sensor 226. This results in the first autofocus pixel sensor 226 and the second autofocus pixel sensor 226 having different FWCs.

Moreover, a first grid extension 228 extends laterally over the top of the first photodiode 112 by a distance D11, and a second grid extension 228 extends laterally over the top of the second photodiode 112 by a distance D12, where the distance D11 and the distance D12 may be the same or different distances. For example, the distance D11 may be greater than the distance D12, resulting in the same or different percentages of the areas of the first photodiode 112 and the second photodiode 112 being shielded from incident light. As another example, the distance D11 and the distance D12 may be approximately equal, resulting in different percentages of the areas of the first photodiode 112 and the second photodiode 112 being shielded from incident light.

As further shown in FIG. 8, the metal grid structures 224 and the associated grid extensions 228 over the autofocus pixel sensors 226 may have an approximately trapezoidal cross-section shape or profile. For example, a cross-sectional width of a top surface of the metal grid structures 224 and the associated grid extensions 228 may be less than a cross-sectional width of a bottom surface of the metal grid structures 224 and the associated grid extensions 228. Thus, the cross-sectional width increases from the top surface to the bottom surface for the metal grid structures 224 and the associated grid extensions 228.

As indicated above, FIG. 8 is provided as examples. Other examples may differ from what is described with regard to FIG. 8.

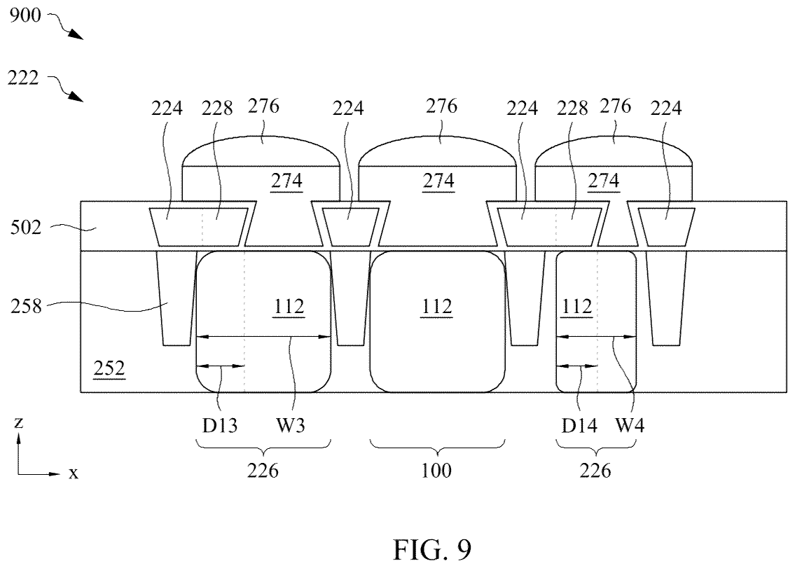

FIG. 9 is a diagram of an example 900 of a pixel sensor array 222 of a sensor die 208 described herein. FIG. 9 illustrates cross-section views of the example 900 of the pixel sensor array 222. In the example 900, the pixel sensor array 222 includes autofocus pixel sensors 226 that have photodiodes 112 of different cross-sectional widths. For example, a first autofocus pixel sensor 226 may have a first photodiode 112 with a first cross-sectional width W3 that is greater than a second cross-sectional width W4 of a second photodiode 112 of a second autofocus pixel sensor 226. This results in the first autofocus pixel sensor 226 and the second autofocus pixel sensor 226 having different FWCs.

Moreover, a first grid extension 228 extends laterally over the top of the first photodiode 112 by a distance D13, and a second grid extension 228 extends laterally over the top of the second photodiode 112 by a distance D14, where the distance D13 and the distance D14 may be the same or different distances. For example, the distance D13 may be greater than the distance D14, resulting in the same or different percentages of the areas of the first photodiode 112 and the second photodiode 112 being shielded from incident light. As another example, the distance D13 and the distance D14 may be approximately equal, resulting in different percentages of the areas of the first photodiode 112 and the second photodiode 112 being shielded from incident light.

As further shown in FIG. 8, the metal grid structures 224 and the associated grid extensions 228 over the autofocus pixel sensors 226 may have an approximately inverted trapezoidal cross-section shape or profile. For example, a cross-sectional width of a top surface of the metal grid structures 224 and the associated grid extensions 228 may be greater than a cross-sectional width of a bottom surface of the metal grid structures 224 and the associated grid extensions 228. Thus, the cross-sectional width decreases from the top surface to the bottom surface for the metal grid structures 224 and the associated grid extensions 228.

As indicated above, FIG. 9 is provided as examples. Other examples may differ from what is described with regard to FIG. 9.

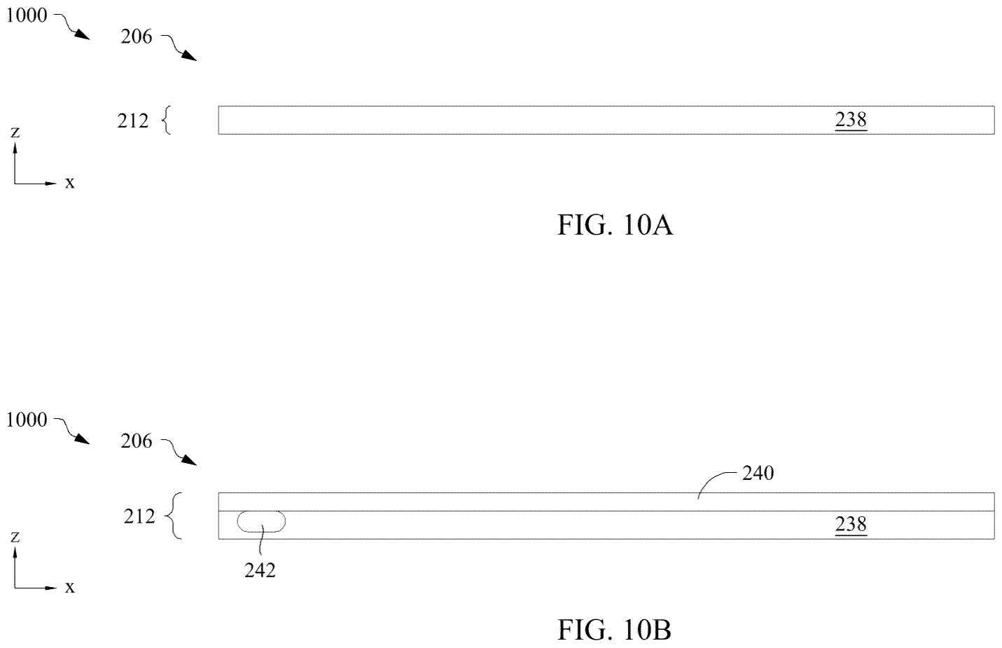

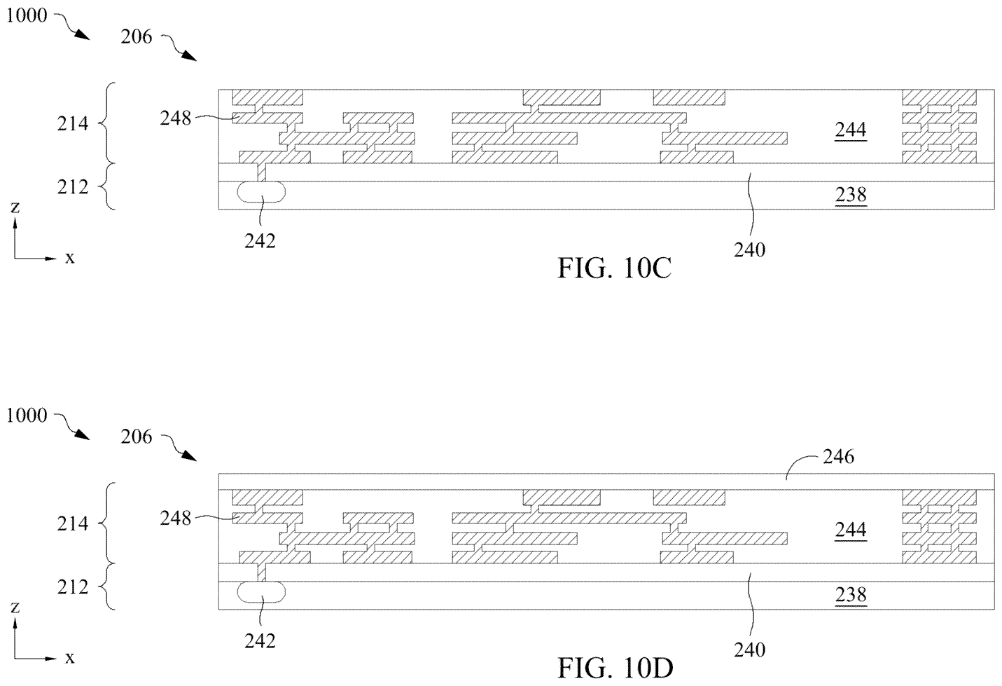

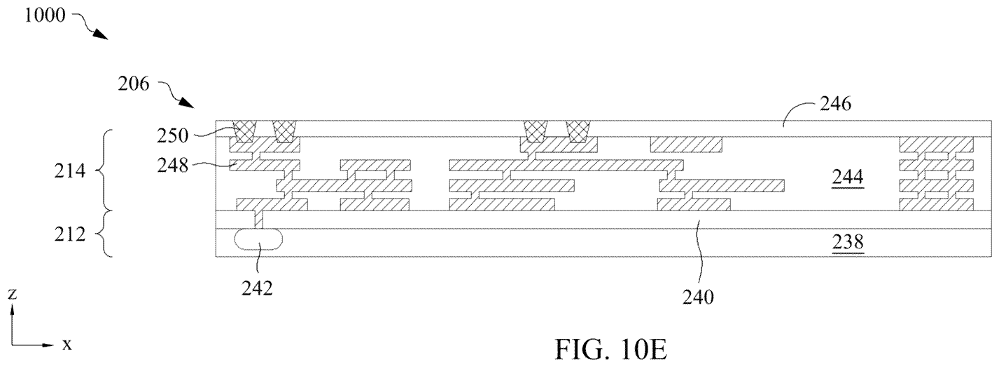

FIGS. 10A-10E are diagrams of an example implementation 1000 of forming a circuitry die 206 (or a portion thereof) described herein. In some implementations, one or more of the semiconductor processing operations described in connection with FIGS. 10A-10E may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 10A, the semiconductor layer 238 of the device layer 212 of the circuitry die 206 is provided. The semiconductor layer 238 may be provided in the form of a semiconductor wafer such as a silicon (Si) wafer may be provided as an SOI wafer, and/or another type of semiconductor work piece.

As shown in FIG. 10B, one or more devices 242 may be formed in and/or on the semiconductor layer 238. One or more semiconductor processing tools may be used to form one or more portions of the devices 242. For example, a deposition tool may be used to perform various deposition operations to deposit layers of the devices 242, and/or to deposit photoresist layers for etching the semiconductor layer 238 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the semiconductor layer 238 and/or portions of the deposited layers to form the devices 242. As another example, a planarization tool may be used to planarize portions of the devices 242. As another example, a plating tool may be used to deposit metal structures and/or layers of the devices 242.

As further shown in FIG. 10B, a dielectric layer 240 may be deposited over and/or on the semiconductor layer 238 and over and/or on the devices 242. A deposition tool may be used to deposit the dielectric layer 240 using a physical vapor deposition (PVD) technique, an atomic layer deposition (ALD) technique, a chemical vapor deposition (CVD) technique, an oxidation technique, another type of deposition technique. In some implementations, a planarization tool may be used to planarize the dielectric layer 240 after the dielectric layer 240 is deposited.

As shown in FIG. 10C, a first portion of an interconnect layer 214 of the circuitry die 206 is formed above the device layer 212. To form the first portion of the interconnect layer 214, a deposition tool may be used to deposit a dielectric layer 244 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 244 after the dielectric layer 244 is deposited.

A deposition tool, an exposure tool, a developer tool, an etch tool, a planarization tool, a plating tool, and/or another semiconductor processing tool may be used to perform various operations to form interconnect structures 248 in the first portion of the interconnect layer 214. A deposition tool and/or a plating tool may be used to deposit the interconnect structures 248 using a PVD technique, an ALD technique, a CVD technique, an electroplating technique, and/or another deposition technique. In some implementations, a planarization tool may be used to planarize the interconnect structures 248 after the interconnect structures 248 are deposited.

In some implementations, first portion of the interconnect layer 214 is built up in the z-direction in a plurality of via layers (V-layers) and metallization layers (M-layers). For example, a first portion of the dielectric layer 244 may be formed, recesses may be formed in the first portion of the dielectric layer 244, and first interconnect structures 248 (e.g., a V0 via layer, an MO metallization layer) may be formed in the recesses. A second portion of the dielectric layer 244 may be formed, recesses may be formed in the second portion of the dielectric layer 244, and second interconnect structures 248 (e.g., a V1 via layer, an MI metallization layer) may be formed in the recesses. The remaining via layers and/or metallization layers of the first portion of the interconnect layer 214 may be formed in a similar manner.

As shown in FIGS. 10D and 10E, a second portion of the interconnect layer 214 may be formed, and the second portion of the interconnect layer 214 may include a bonding layer 246 and bonding structures 250. As shown in FIG. 10D, the bonding layer 246 may be formed over and/or on the dielectric layer 244, and over and/or on the top-most interconnect structures 248. A deposition tool may be used to deposit the bonding layer 246 using a PVD technique, an ALD technique, a CVD technique, an oxidation technique, another deposition technique. In some implementations, a planarization tool may be used to planarize the bonding layer 246 after the bonding layer 246 is deposited.

As shown in FIG. 10E, the bonding structures 250 may be formed in the bonding dielectric layer 246. For example, a deposition tool, an exposure tool, and a developer tool may be used to form a patterned masking layer on the bonding layer 246. An etch tool may be used to etch the bonding layer 246 (e.g., using a wet etch technique, a dry etch technique) to form recesses in the bonding layer 246. A deposition tool and/or a plating tool may be used to deposit the bonding structures 250 in the recess using a CVD technique, a PVD technique, an ALD technique, an electroplating technique, and/or another deposition technique. In some implementations, a planarization tool may perform a planarization operation to planarize the bonding structures 250 after the bonding structures 250 are deposited.

As indicated above, FIGS. 10A-10E are provided as an example. Other examples may differ from what is described with regard to FIGS. 10A-10E.

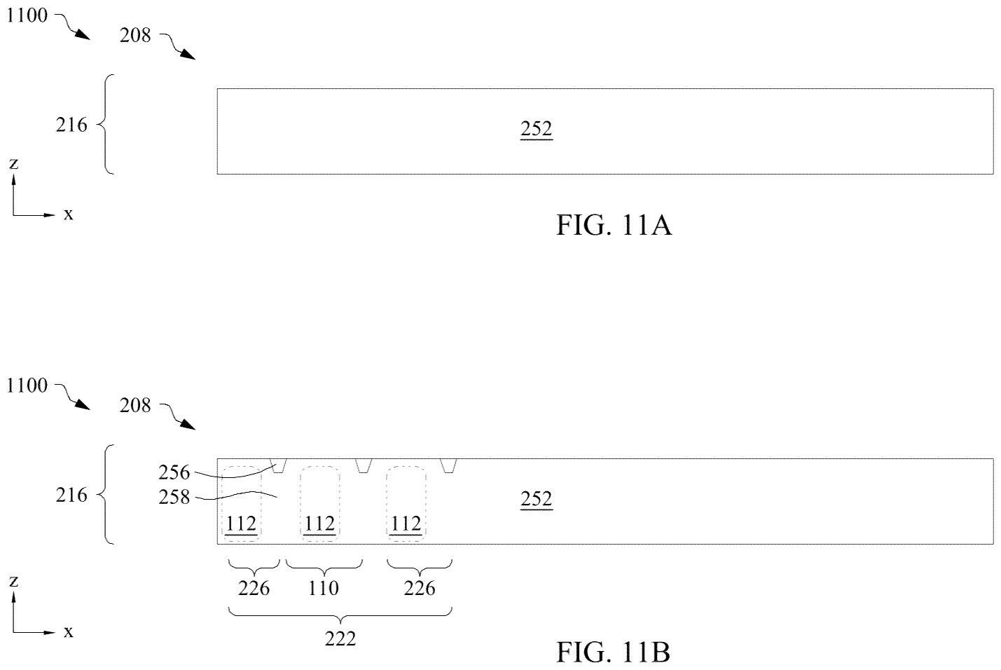

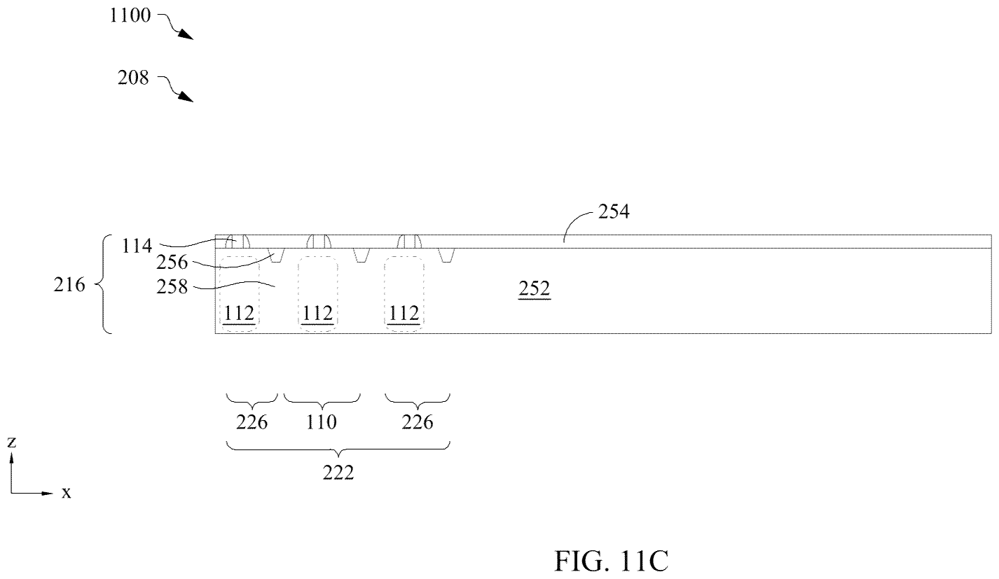

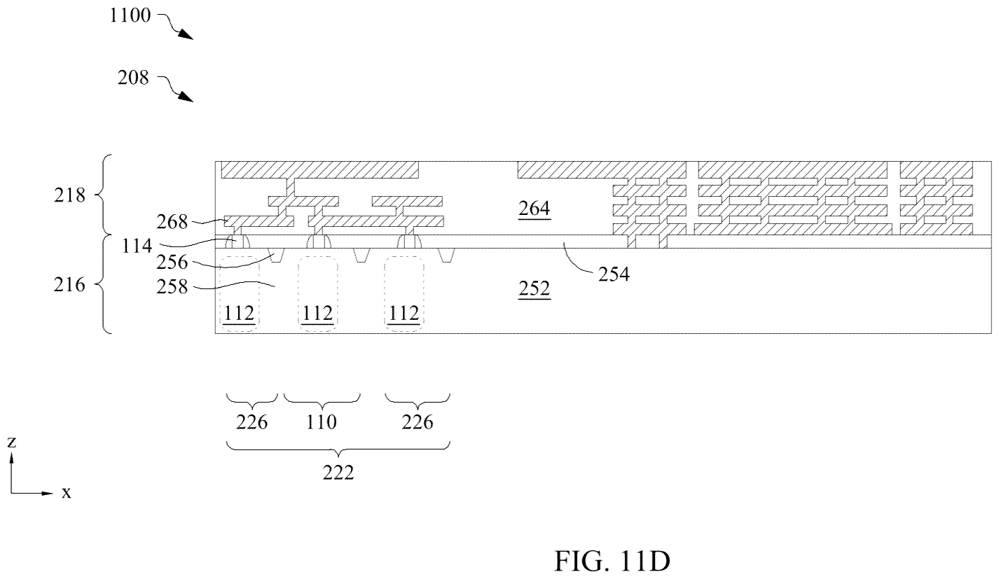

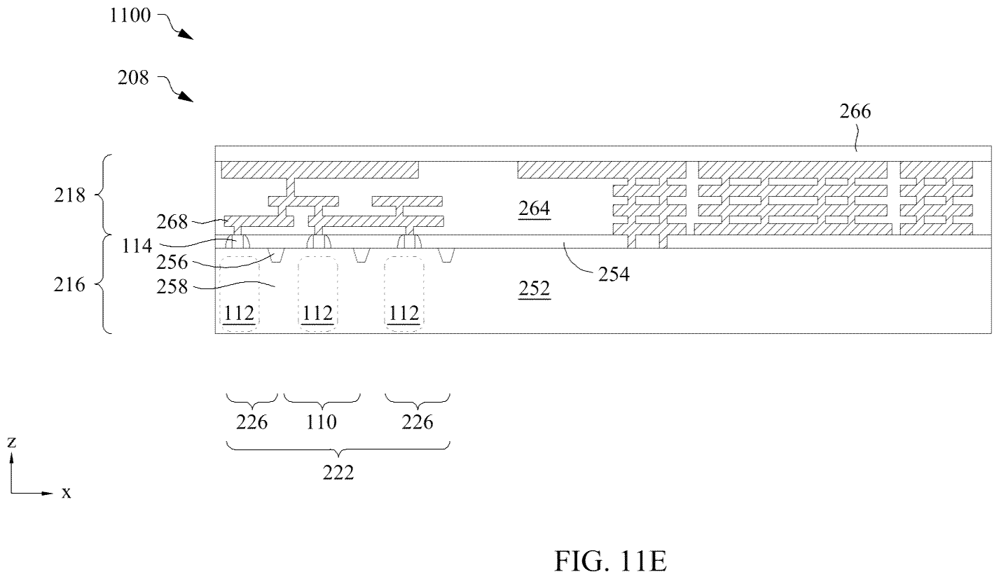

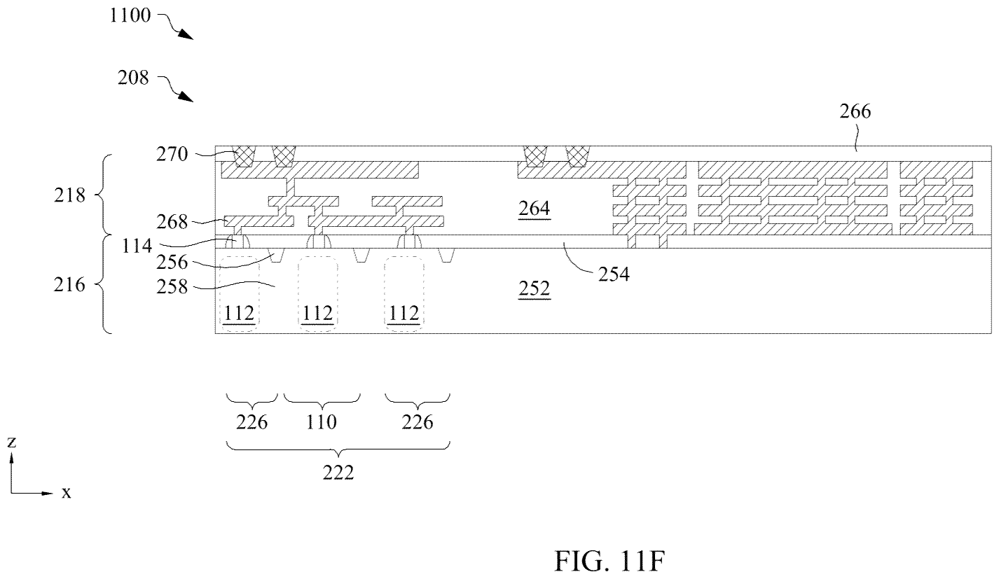

FIGS. 11A-11F are diagrams of an example implementation 1100 of forming a sensor die 208 (or a portion thereof) described herein. In some implementations, one or more of the semiconductor processing operations described in connection with FIGS. 11A-11F may be performed using one or more semiconductor processing tools, such as a deposition tool, an exposure tool, a developer tool, an etch tool, a planarization tool, a plating tool, an ion implantation tool, and/or a wafer/die transport tool, among other examples.

Turning to FIG. 11A, the semiconductor layer 252 of the device layer 216 of the sensor die 208 is provided. The semiconductor layer 252 may be provided in the form of a semiconductor wafer such as a silicon (Si) wafer may be provided as an SOI wafer, and/or another type of semiconductor work piece.

As shown in FIG. 11B, photodiodes 112 of pixel sensors 100 and autofocus pixel sensors 226 of a pixel sensor array 222 of the sensor die 208 may be formed in the semiconductor layer 252 in the device layer 216 of the sensor die 208. In some implementations, an ion implantation tool may be used to implant ions into the semiconductor layer 252 to form a P-N junction between a p-doped region of the semiconductor layer 252 and an n-doped region of the semiconductor layer 252, or to form a P-I-N junction between p-doped region of the semiconductor layer 252, an n-doped region of the semiconductor layer 252, and an intrinsic (e.g., undoped) semiconductor region for a photodiode 112.

As further shown in FIG. 11B, STI structures 256 may be formed in the semiconductor layer 252 (e.g., from the front side of the semiconductor layer 252) such that the STI structures 256 are located between the photodiodes 112. In some implementations, the STI structures 256 are formed after the photodiodes 112 are formed. In some implementations, the STI structures 256 are formed prior to formation of the photodiodes 112. A deposition tool, an exposure tool, and a developer tool may be used to form a patterned masking layer on the semiconductor layer 252. An etch tool may be used to etch into the semiconductor layer 252 from the front side of the semiconductor layer 252 (e.g., using a wet etch technique, a dry etch technique) to form the recesses in the front side of the semiconductor layer 252. A deposition tool may be used to deposit the STI structures 256 in the recesses using a CVD technique, a PVD technique, an ALD technique, an oxidation technique, and/or another deposition technique. In some implementations, a planarization tool may perform a planarization operation to planarize the STI structures 256 after the STI structures 256 are deposited.

As shown in FIG. 11C, transfer gates 114 may be formed over and/or on the front side surface of the semiconductor layer 252 for the pixel sensors 100 and autofocus pixel sensors 226 of the pixel sensor array 222. Forming a transfer gate 114 may include deposing a gate dielectric layer on the front side surface of the semiconductor layer 252, depositing a gate electrode on the gate dielectric layer, and/or forming sidewall spacers on sidewalls of the gate electrode, among other examples.

As further shown in FIG. 11C, a dielectric layer 254 may be formed over and/or on the front side of the semiconductor layer 252, and over and/or on the transfer gates 114. A deposition tool may be used to deposit the dielectric layer 254 using a CVD technique, a PVD technique, an ALD technique, an electroplating technique, and/or another deposition technique. In some implementations, a planarization tool may perform a planarization operation to planarize the dielectric layer 254 after the dielectric layer 254 is deposited.

As shown in FIG. 11D, a first portion of an interconnect layer 218 of the sensor die 208 is formed above the device layer 216. To form the first portion of the interconnect layer 218, a deposition tool may be used to deposit a dielectric layer 264 (which may include one or more ILD layers, one or more IMD layers, one or more ESLs, and/or one or more of another type of dielectric layer) using a PVD technique, an ALD technique, a CVD technique, an oxidation technique, another deposition technique. In some implementations, a planarization tool may be used to planarize the dielectric layer 264 after the dielectric layer 264 is deposited.

A deposition tool, an exposure tool, a developer tool, an etch tool, a planarization tool, a plating tool, and/or another semiconductor processing tool may be used to perform various operations to form interconnect structures 268 in the first portion of the interconnect layer 218. A deposition tool and/or a plating tool may be used to deposit the interconnect structures 268 using a PVD technique, an ALD technique, a CVD technique, an electroplating technique, and/or another deposition technique. In some implementations, a planarization tool may be used to planarize the interconnect structures 268 after the interconnect structures 268 are deposited.

In some implementations, first portion of the interconnect layer 218 is built up in the z-direction in a plurality of via layers (V-layers) and metallization layers (M-layers). For example, a first portion of the dielectric layer 264 may be formed, recesses may be formed in the first portion of the dielectric layer 264, and first interconnect structures 268 (e.g., a V0 via layer, an MO metallization layer) may be formed in the recesses. A second portion of the dielectric layer 264 may be formed, recesses may be formed in the second portion of the dielectric layer 264, and second interconnect structures 268 (e.g., a V1 via layer, an MI metallization layer) may be formed in the recesses. The remaining via layers and/or metallization layers of the first portion of the interconnect layer 218 may be formed in a similar manner.

As shown in FIGS. 11E and 11F, a second portion of the interconnect layer 218 may be formed, and the second portion of the interconnect layer 218 may include a bonding layer 266 and bonding structures 270. As shown in FIG. 11E, the bonding layer 266 may be formed over and/or on the dielectric layer 264, and over and/or on the top-most interconnect structures 268. A deposition tool may be used to deposit the bonding layer 266 using a PVD technique, an ALD technique, a CVD technique, an oxidation technique, another deposition technique. In some implementations, a planarization tool may be used to planarize the bonding layer 266 after the bonding dielectric layer 266 is deposited.

As shown in FIG. 11F, the bonding structures 270 may be formed in the bonding layer 266. For example, a deposition tool, an exposure tool, and a developer tool may be used to form a patterned masking layer on the bonding layer 266. An etch tool may be used to etch the bonding layer 266 (e.g., using a wet etch technique, a dry etch technique) to form recesses in the bonding layer 266. A deposition tool and/or a plating tool may be used to deposit the bonding structures 270 in the recess using a CVD technique, a PVD technique, an ALD technique, an electroplating technique, and/or another deposition technique. In some implementations, a planarization tool may perform a planarization operation to planarize the bonding structures 270 after the bonding structures 270 are deposited.

As indicated above, FIGS. 11A-11F are provided as an example. Other examples may differ from what is described with regard to FIGS. 11A-11F.

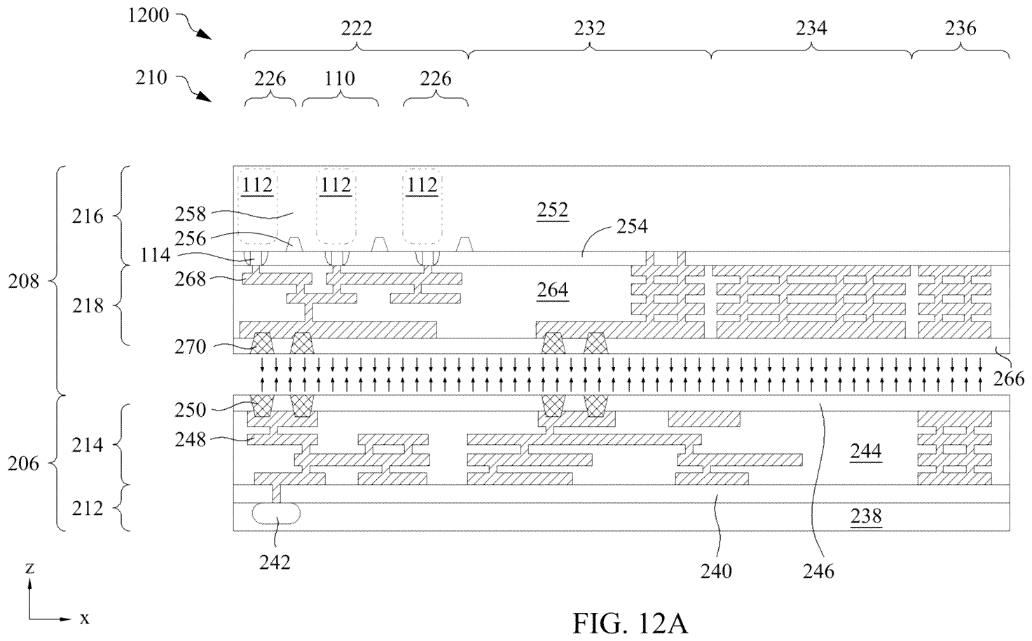

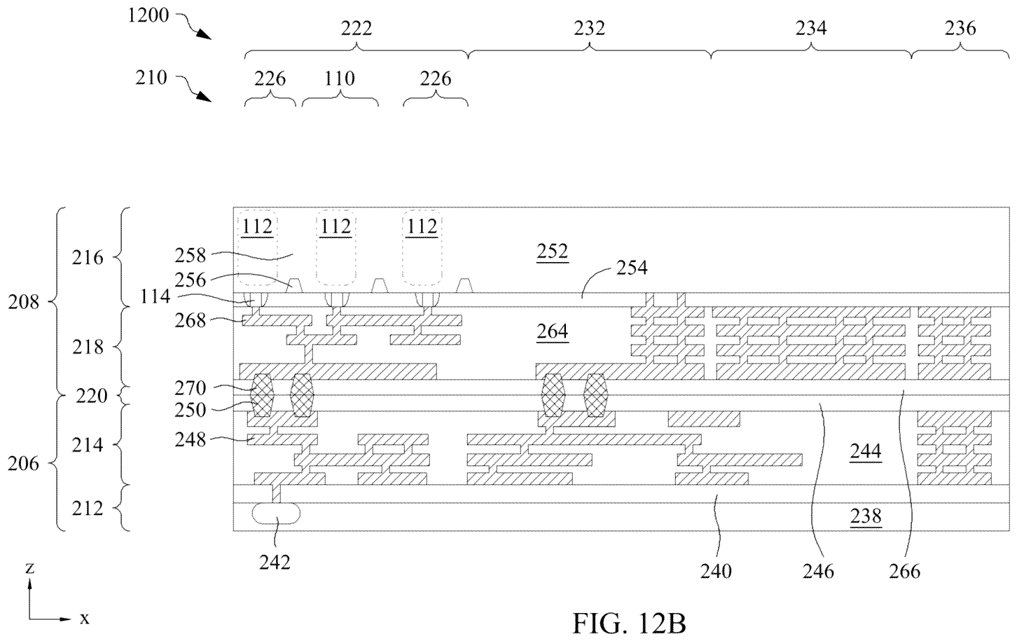

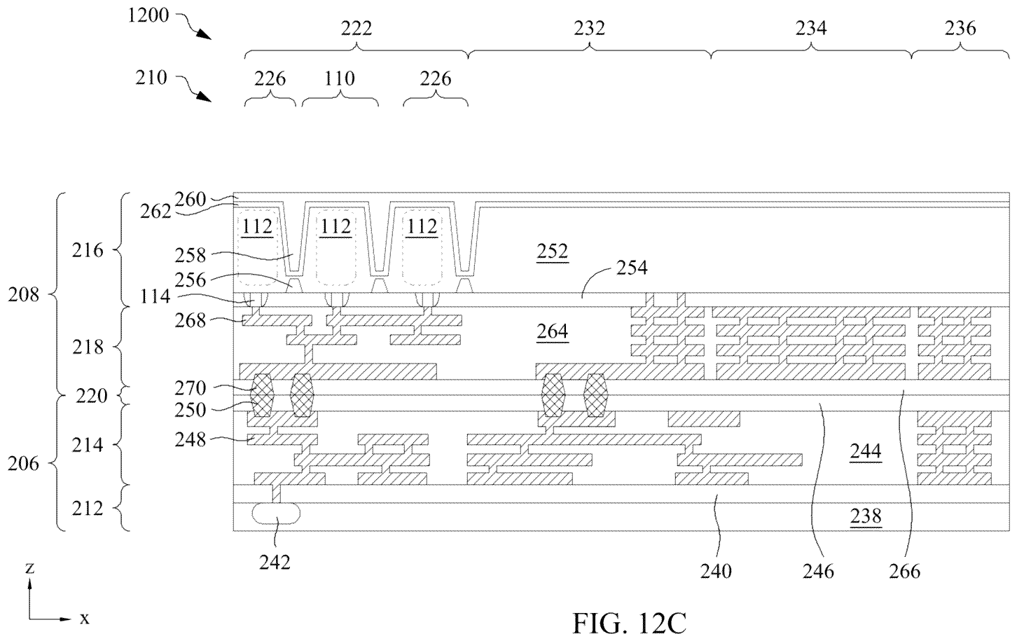

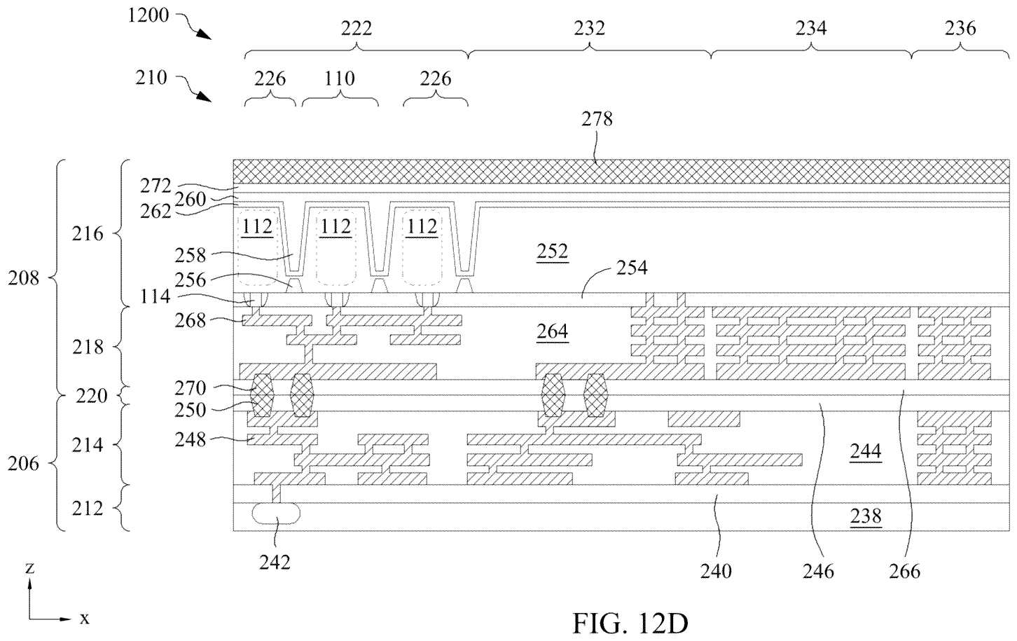

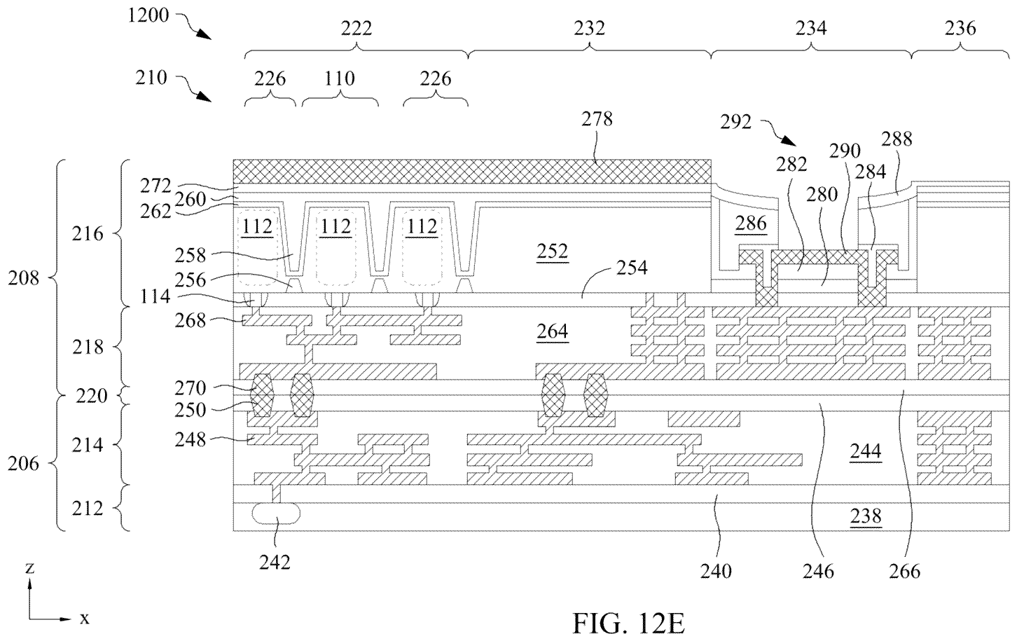

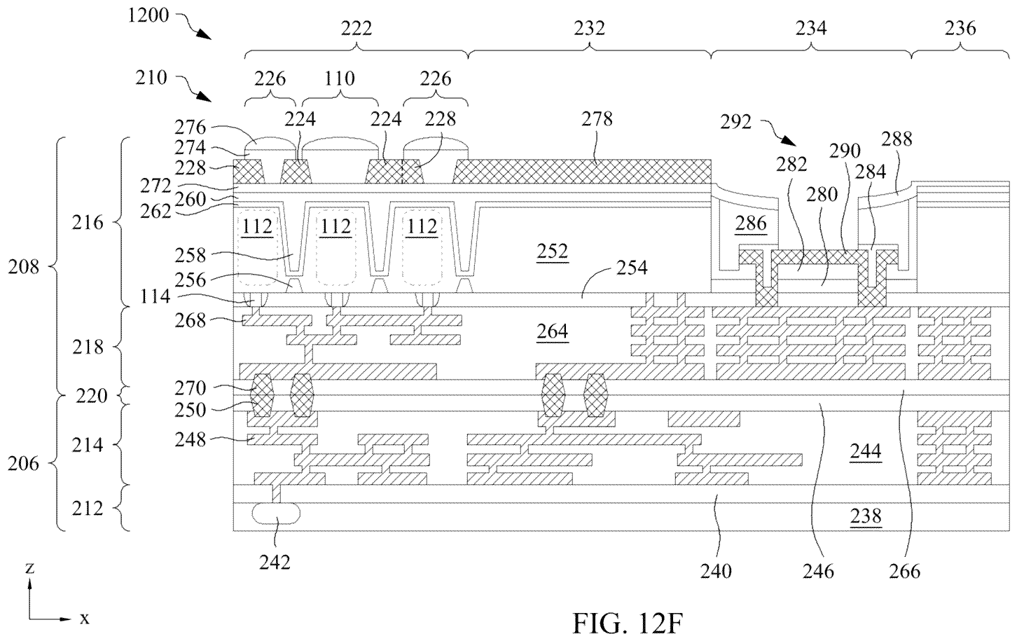

FIGS. 12A-12F are diagrams of an example implementation 1200 of forming an image sensor device 210 (or a portion thereof) described herein. In some implementations, one or more of the semiconductor processing operations described in connection with FIGS. 12A-12F may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIGS. 12A and 12B, a bonding operation is performed to bond a circuitry die 206 and a sensor die 208 to form the image sensor device 210. The circuitry die 206 and the sensor die 208 may be bonded at a bonding interface 220, which may include the bonding layers 246 and 266 (respectively of the circuitry die 206 and the sensor die 208), and the bonding structures 250 and 270 (respectively of the circuitry die 206 and the sensor die 208). A bonding tool may be used to form a dielectric-to-dielectric bond between the bonding layers 246 and 266 at the bonding interface 220, and to form a metal-to-metal bond between the bonding structures 250 and 270 at the bonding interface 220.

As shown in FIG. 12B, after bonding, the circuitry die 206 and the sensor die 208 are stacked or vertically arranged in the z-direction in the image sensor device 210. The interconnect layer 214 of the circuitry die 206 and the interconnect layer 218 of the sensor die 208 are facing toward each other in the image sensor device 210, and the device layer 212 of the circuitry die 206 and the device layer 216 of the sensor die 208 are facing away from each other.

As shown in FIG. 12C, the DTI structure 258 may be formed in the semiconductor layer 252 (e.g., in the back side of the semiconductor layer 252) and around the photodiodes 112 in the semiconductor layer 252. For example, a deposition tool, an exposure tool, and a developer tool may be used to form a patterned masking layer on the semiconductor layer 252. An etch tool may be used to etch the semiconductor layer 252 (e.g., using a wet etch technique, a dry etch technique) from the back side of the semiconductor layer 252 to form trenches in the back side of the semiconductor layer 252. The trenches are above the STI structures 256 and alongside the photodiodes 112.

A deposition tool may be used to conformally deposit a dielectric liner 262 of the DTI structure 258 in the trenches and on the back side surface of the semiconductor layer 252 using a CVD technique, an ALD technique, and/or another conformal deposition technique. A deposition tool may be used to deposit the dielectric material 260 of the DTI structure 258 on the dielectric liner 262 in the trenches and above the semiconductor layer 252 using a CVD technique, a PVD technique, an ALD technique, an oxidation technique, and/or another deposition technique. In some implementations, a planarization tool may perform a planarization operation to planarize the dielectric material 260 above the semiconductor layer 252, which may remain as a buffer layer.

As shown in FIG. 12D, a passivation layer 272 may be formed over and/or on the buffer layer, and a metal layer 278 may be formed over and/or on the passivation layer over the back side of the semiconductor layer 252. A deposition tool and/or a plating tool may be used to deposit the passivation layer 272 using a CVD technique, a PVD technique, an ALD technique, an oxidation technique, and/or another deposition technique. In some implementations, a planarization tool may perform a planarization operation to planarize the passivation layer 272 after the passivation layer 272 is deposited. A deposition tool and/or a plating tool may be used to deposit the metal layer 278 using a CVD technique, a PVD technique, an ALD technique, an electroplating technique, and/or another deposition technique. In some implementations, a planarization tool may perform a planarization operation to planarize the metal layer 278 after the metal layer 278 is deposited.

As shown in FIG. 12E, various layers and/or structures may be formed in the bonding pad region 234 of the image sensor device 210. For example, a recess may be formed through the metal layer 278, through the passivation layer 272, through the buffer layer, through the dielectric liner 262, and/or through the semiconductor layer 252 to the dielectric layer 254. In some implementations, a deposition tool, an exposure tool, and a developer tool may be used to form a patterned masking layer on the metal layer 278. An etch tool may be used to etch the through the metal layer 278, through the passivation layer 272, through the buffer layer, through the dielectric liner 262, through the semiconductor layer 252 (e.g., using a wet etch technique, a dry etch technique) from the back side of the semiconductor layer 252 to form the recess.

A dielectric layer 280 may be formed in the recess on the dielectric layer 254. A dielectric layer 282 may be formed on the dielectric layer 280. A deposition tool may be used to deposit the dielectric layers 280 and 282 in the recess using a CVD technique, a PVD technique, an ALD technique, an oxidation technique, and/or another deposition technique.

Openings may be formed through the dielectric layers 280, 282, and 254 such that an interconnect structure 268 in the interconnect layer 218 is exposed through the recesses. A bonding pad structure 290 may be formed in the openings such that the bonding pad structure 290 lands on the interconnect structure 268. The bonding pad structure 290 is also formed on the dielectric layer 282.

In some implementations, a deposition tool, an exposure tool, and a developer tool may be used to form a patterned masking layer on the dielectric layer 282. An etch tool may be used to etch the through the dielectric layer 282, through the dielectric layer 280, and through the dielectric layer 254 (e.g., using a wet etch technique, a dry etch technique) to form the recesses. A deposition tool and/or a plating tool may be used to deposit the bonding pad structure 290 in the recess using a CVD technique, a PVD technique, an ALD technique, an electroplating technique, and/or another deposition technique.

A dielectric layer 284 may be formed on the bonding pad structure 290, and dielectric layers 286 and 288 may be deposited to fill in the recess in the bonding pad region 234. A bonding pad opening 292 may be formed through the dielectric layers 284, 286, and 288 to expose the bonding pad structure 290.

A deposition tool may be used to deposit the dielectric layers 284, 286, and 288 in the recess using a CVD technique, a PVD technique, an ALD technique, an oxidation technique, and/or another deposition technique. In some implementations, a deposition tool, an exposure tool, and a developer tool may be used to form a patterned masking layer on the dielectric layer 288. An etch tool may be used to etch the through the dielectric layers 284, 286, and 288 (e.g., using a wet etch technique, a dry etch technique) to form the bonding pad opening 292.

As shown in FIG. 12F, the metal layer 278 in the pixel sensor array 222 is etched to form the metal grid structure 224 and the associated grid extensions 228 that extend laterally over at least a portion of the photodiodes 112 of the autofocus pixel sensors 226.

In some implementations, a deposition tool, an exposure tool, and a developer tool may be used to form a patterned masking layer on the metal layer 278. An etch tool may be used to etch the through the metal layer 278 to the passivation layer 272 (e.g., using a wet etch technique, a dry etch technique) remove portions of the metal layer 278. Remaining portions of the metal layer 278 in the pixel sensor array 222 correspond to the metal grid structure 224 above the DTI structure 258, and the grid extensions 228 that extend laterally outward from the metal grid structure 224 and the DTI structure 258.

As further shown in FIG. 12F, color filter regions 274 are formed in openings in the metal grid structure 224 such that the color filter regions 274 are located above and/or over the photodiodes 112 of the pixel sensors 100 and the photodiodes 112 of the autofocus pixel sensors 226. Micro-lenses 276 are formed on the color filter regions 274.

As indicated above, FIGS. 12A-12F are provided as an example. Other examples may differ from what is described with regard to FIGS. 12A-12F.

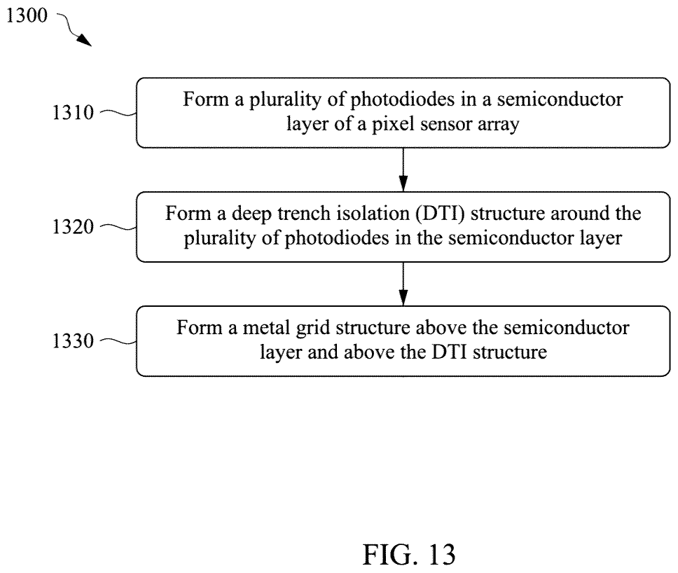

FIG. 13 is a flowchart of an example process 1300 associated with forming a pixel sensor array described herein. In some implementations, one or more of the semiconductor processing operations described in connection with FIG. 13 may be performed using one or more semiconductor processing tools, such as a deposition tool, an exposure tool, a developer tool, an etch tool, a planarization tool, a plating tool, an ion implantation tool, and/or a wafer/die transport tool, among other examples.

As shown in FIG. 13, process 1300 may include forming a plurality of photodiodes in a semiconductor layer of a pixel sensor array (block 1310). For example, one or more semiconductor processing tools may be used to form a plurality of photodiodes 112 in a semiconductor layer 252 of a pixel sensor array 222, as described herein. The semiconductor layer 252 may be included in a sensor die 208.

As further shown in FIG. 13, process 1300 may include forming a DTI structure around the plurality of photodiodes in the semiconductor layer (block 1320). For example, one or more semiconductor processing tools may be used to form a DTI structure 258 around the plurality of photodiodes 112 in the semiconductor layer 252, as described herein.

As further shown in FIG. 13, process 1300 may include forming a metal grid structure above the semiconductor layer and above the DTI structure (block 1330). For example, one or more semiconductor processing tools may be used to form a metal grid structure 224 above the semiconductor layer 252 and above the DTI structure 258, as described herein. In some implementations, forming the metal grid structure 224 includes forming a plurality of grid extensions 228 that extend laterally outward from the metal grid structure 224 and from the DTI structure 258. In some implementations, each of the plurality of grid extensions 228 extends at least partially over a respective photodiode 112 of the plurality of photodiodes 112.

Process 1300 may include additional implementations, such as any single implementation or any combination of implementations described below and/or in connection with one or more other processes described elsewhere herein.

In a first implementation, forming the metal grid structure 224 includes depositing a layer of metal material (e.g., a metal layer 278) above the semiconductor layer 252, and etching the layer of metal material to form the metal grid structure 224 such that a cross-sectional width of a top surface of a section of the metal grid structure 224 is greater than a cross-sectional width of a bottom surface of the section of the metal grid structure 224.

In a second implementation, alone or in combination with the first implementation, forming the metal grid structure 224 includes depositing a layer of metal material (e.g., a metal layer 278) above the semiconductor layer 252, and etching the layer of metal material to form the metal grid structure 224 such that a cross-sectional width of a top surface of a section of the metal grid structure 224 is less than a cross-sectional width of a bottom surface of the section of the metal grid structure 224.

In a third implementation, alone or in combination with one or more of the first and second implementations, forming the plurality of grid extensions 228 includes forming the plurality of grid extensions 228 such that two or more of the plurality of grid extensions 228 have different top view shapes.

In a fourth implementation, alone or in combination with one or more of the first through third implementations, forming the plurality of grid extensions 228 includes forming a first grid extension 228, of the plurality of grid extensions 228, such that the first grid extension 228 covers a first percentage of an area of a top surface of a first photodiode 112 of the plurality of photodiodes 112, and forming a second grid extension 228, of the plurality of grid extensions 228, such that the second grid extension 228 covers a second percentage of an area of a top surface of a second photodiode 112 of the plurality of photodiodes 112, where the first percentage is greater than the second percentage.

In a fifth implementation, alone or in combination with one or more of the first through fourth implementations, forming the plurality of photodiodes 112 includes forming the first photodiode 112 to a first cross-sectional width, and forming the second photodiode 112 to a second cross-sectional width, where the first cross-sectional width is greater than the second cross-sectional width.

In a sixth implementation, alone or in combination with one or more of the first through fifth implementations, the process 1300 includes forming a plurality of color filter regions 274 over the plurality of photodiodes 112, where a subset of the plurality of color filter regions 274 are formed in between the metal grid structure 224 and the plurality of grid extensions 228.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, autofocus functionality may be integrated into a pixel sensor array of an image sensor device described herein by including autofocus pixel sensors with imaging pixel sensors in the pixel sensor array. A metal grid structure is included around the autofocus pixel sensors and the imaging pixel sensors in the pixel sensor array. Moreover, the metal grid structure includes grid extensions, which are portions of the metal grid structure that extend laterally outward over at least a portion of photodiodes of the autofocus pixel sensors, thereby shielding the portions of the photodiodes from incident light. The autofocus pixel sensors may be arranged in pairs in the pixel sensor array such that opposing sides of the photodiodes of the autofocus pixel sensors in a pair are shielded by grid extensions. This results in a phase difference between the incident light sensed by the autofocus pixel sensors in the pair. The phase difference is used for determining the focus of the pixel sensor array. Thus, the grid extensions of the metal grid structure and the autofocus pixel sensors enable PDAF to be integrated into the pixel sensor array for high-speed autofocus performance. Moreover, grid extensions may cover different percentages of the area of the photodiodes of different autofocus pixel sensors, which enables high-speed autofocus performance in both high and low illumination scenarios.

As described in greater detail above, some implementations described herein provide a pixel sensor array. The pixel sensor array includes a plurality of pixel sensors arranged in a grid. The pixel sensor array includes a metal grid structure above photodiodes of the plurality of pixel sensors, where the metal grid structure surrounds the photodiodes of the plurality of pixel sensors, and where the metal grid structure includes grid extensions that laterally extend from the metal grid structure and over at least a portion of photodiodes of a subset of the plurality of pixel sensors.

As described in greater detail above, some implementations described herein provide an image sensor device. An image sensor device includes a plurality of pixel sensors arranged in a pixel sensor array. The an image sensor device includes a metal grid structure above photodiodes of the plurality of pixel sensors, where the metal grid structure surrounds the photodiodes of the plurality of pixel sensors, and where the metal grid structure includes: a first grid extension that laterally extends from the metal grid structure over at least a portion of a first photodiode of a first pixel sensor of the plurality of pixel sensors, and a second grid extension that laterally extends from the metal grid structure over at least a portion of a second photodiode of a second pixel sensor of the plurality of pixel sensors, where a first extension distance, that the first grid extension laterally extends over the at least the portion of the first photodiode, is greater than a second extension distance that the second grid extension laterally extends over the at least the portion of the second photodiode.

As described in greater detail above, some implementations described herein provide a method. The method includes forming a plurality of photodiodes in a semiconductor layer of a pixel sensor array. The method includes forming a DTI structure around the plurality of photodiodes in the semiconductor layer. The method includes forming a metal grid structure above the semiconductor layer and above the DTI structure, where forming the metal grid structure includes forming a plurality of grid extensions that extend laterally outward from the metal grid structure and from the DTI structure, and where each of the plurality of grid extensions extends at least partially over a respective photodiode of the plurality of photodiodes.

The terms “approximately” and “substantially” can indicate a value of a given quantity that varies within 5% of the value (e.g., +1%, +2%, +3%, +4%, +5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A pixel sensor array, comprising:
a plurality of pixel sensors arranged in a grid; and
a metal grid structure above photodiodes of the plurality of pixel sensors,
wherein the metal grid structure surrounds the photodiodes of the plurality of pixel sensors, and
wherein the metal grid structure includes grid extensions that laterally extend from the metal grid structure and over at least a portion of photodiodes of a subset of the plurality of pixel sensors.

2. The pixel sensor array of claim 1, wherein the grid extensions comprise:
a first grid extension over a first portion of a first photodiode of a first pixel sensor of the subset of the plurality of pixel sensors; and
a second grid extension over a second portion of a second photodiode of a second pixel sensor of the subset of the plurality of pixel sensors,
wherein the first portion is facing away from the second photodiode, and
wherein the second portion is facing away from the first photodiode.

3. The pixel sensor array of claim 1, wherein the grid extensions comprise:
a first grid extension over a first portion of a first photodiode, of a first pixel sensor of the subset of the plurality of pixel sensors, from a first side of the first photodiode; and
a second grid extension over a second portion of a second photodiode, of a second pixel sensor of the subset of the plurality of pixel sensors, from a second side of the first photodiode,
wherein the first side and the second side are approximately orthogonal.

4. The pixel sensor array of claim 3, further comprising:
a first color filter above the first photodiode; and
a second color filter above the second photodiode,
wherein the first color filter and the second color filter are configured to pass a same wavelength range for incident light.

5. The pixel sensor array of claim 1, wherein a cross-sectional width of a top surface of the grid extensions is less than a cross-sectional width of a bottom surface of the grid extensions.

6. The pixel sensor array of claim 1, wherein a cross-sectional width of a top surface of the grid extensions is greater than a cross-sectional width of a bottom surface of the grid extensions.

7. The pixel sensor array of claim 1, wherein the grid extensions each extend laterally and approximately perpendicular to a deep trench isolation (DTI) structure that extends around the photodiodes.

8. An image sensor device comprising:
a plurality of pixel sensors arranged in a pixel sensor array; and
a metal grid structure above photodiodes of the plurality of pixel sensors;
wherein the metal grid structure surrounds the photodiodes of the plurality of pixel sensors, and
wherein the metal grid structure includes:
a first grid extension that laterally extends from the metal grid structure over at least a portion of a first photodiode of a first pixel sensor of the plurality of pixel sensors; and
a second grid extension that laterally extends from the metal grid structure over at least a portion of a second photodiode of a second pixel sensor of the plurality of pixel sensors,
wherein a first extension distance, that the first grid extension laterally extends over the at least the portion of the first photodiode, is different than a second extension distance that the second grid extension laterally extends over the at least the portion of the second photodiode.

9. The image sensor device of claim 8, wherein a cross-sectional width of the first photodiode is greater than a cross-sectional width of the second photodiode.

10. The image sensor device of claim 8, wherein a cross-sectional width of the first photodiode and a cross-sectional width of the second photodiode are approximately equal.

11. The image sensor device of claim 8, wherein the first grid extension and the second grid extension each have an approximately triangular top view shape.

12. The image sensor device of claim 8, wherein the first grid extension has an approximately rectangular top view shape; and
wherein the second grid extension has an approximately triangular top view shape.

13. The image sensor device of claim 8, wherein a cross-sectional width of a top surface of the first grid extension is less than a cross-sectional width of a bottom surface of the first grid extension.

14. The image sensor device of claim 8, wherein a cross-sectional width of a top surface of the first grid extension is greater than a cross-sectional width of a bottom surface of the first grid extension.

15. A method, comprising:
forming a plurality of photodiodes in a semiconductor layer of a pixel sensor array;
forming a deep trench isolation (DTI) structure around the plurality of photodiodes in the semiconductor layer; and
forming a metal grid structure above the semiconductor layer and above the DTI structure,
wherein forming the metal grid structure includes forming a plurality of grid extensions that extend laterally outward from the metal grid structure and from the DTI structure, and
wherein each of the plurality of grid extensions extends at least partially over a respective photodiode of the plurality of photodiodes.

16. The method of claim 15, wherein forming the metal grid structure comprises:
depositing a layer of metal material above the semiconductor layer; and
etching the layer of metal material to form the metal grid structure such that a cross-sectional width of a top surface of a section of the metal grid structure is greater than a cross-sectional width of a bottom surface of the section of the metal grid structure.

17. The method of claim 15, wherein forming the metal grid structure comprises:
depositing a layer of metal material above the semiconductor layer; and
etching the layer of metal material to form the metal grid structure such that a cross-sectional width of a top surface of a section of the metal grid structure is less than a cross-sectional width of a bottom surface of the section of the metal grid structure.

18. The method of claim 15, wherein forming the plurality of grid extensions comprises:
forming the plurality of grid extensions such that two or more of the plurality of grid extensions have different top view shapes.

19. The method of claim 15, wherein forming the plurality of grid extensions comprises:
forming a first grid extension, of the plurality of grid extensions, such that the first grid extension covers a first percentage of an area of a top surface of a first photodiode of the plurality of photodiodes; and
forming a second grid extension, of the plurality of grid extensions, such that the second grid extension covers a second percentage of an area of a top surface of a second photodiode of the plurality of photodiodes,
wherein the first percentage is greater than the second percentage.

20. The method of claim 15, further comprising:
forming a plurality of color filter regions over the plurality of photodiodes, wherein a subset of the plurality of color filter regions are formed in between the metal grid structure and the plurality of grid extensions.
